(19) United States
(12) Patent Application Publication
(10) Pub. No.: US 2014/0319971 A1
(43) Pub. Date: Oct. 30, 2014

(54) FRAMELESS ACTUATOR APPARATUS, SYSTEM, AND METHOD

(71) Applicant: Bayer MaterialScience AG, Leverkusen (DE)

(72) Inventors: Mikyong Yoo, Palo Alto, CA (US); Willam D. Sutherland, Sunnyvale, CA (US); Xina Quan, Saratoga, CA (US); Anthony Obispo, San Jose, CA (US); Junfeng Mei, Sunnyvale, CA (US)

(21) Appl. No.: 13/979,868

(22) PCT Filed: Jan. 17, 2012
(86) PCT No.: PCT/US2012/021511

§ 371 Date: Nov. 7, 2013

Related U.S. Application Data
(60) Provisional application No. 61/433,640, filed on Jan. 18, 2011.
(60) Provisional application No. 61/442,913, filed on Feb. 15, 2011.
(60) Provisional application No. 61/447,827, filed on Mar. 1, 2011.
(60) Provisional application No. 61/477,712, filed on Apr. 21, 2011.
(60) Provisional application No. 61/545,292, filed on Oct. 10, 2011.

(51) Int. Cl. H01L 41/053; H01L 41/23

(52) U.S. Cl. CPC H01L 41/053; H01L 41/23
USPC 310/345; 310/348; 29/829

(57) ABSTRACT

A film actuator is disclosed. The actuator includes a frameless actuator film. The frameless actuator film includes at least one elastomeric dielectric film disposed between first and second electrodes, at least one adhesive applied on one side of the frameless actuator film. It can also include a second adhesive applied on an opposite side of the frameless actuator film. A method of making the actuator is disclosed. A configurable actuator element also is disclosed.

### CROSS REFERENCE TO RELATED APPLICATION

This application claims the benefit, under 35 USC §119(e), of U.S. provisional patent application numbers: 61/433,640, filed Jan. 18, 2011, entitled “FRAME-LESS DESIGN CONCEPT AND PROCESS”; 61/442,913, filed Feb. 15, 2011, entitled “FRAME-LESS DESIGN”; 61/447,827, filed Mar. 1, 2011, entitled “FRAMELESS ACTUATOR, LAMINATION AND CASING”; 61/477,712, filed Apr. 21, 2011, entitled “FRAMELESS APPLICATION”; and 61/545,292, filed Oct. 10, 2011, entitled “AN ALTERNATIVE TO Z-MODE ACTUATORS”; the entire disclosure of each of which is hereby incorporated by reference.

### FIELD OF THE INVENTION

In various embodiments, the present disclosure relates generally to apparatuses, systems, and methods for incorporating thin film electroactive polymer devices. More specifically, the present disclosure relates to a frameless actuator module for moving and/or vibrating surfaces and components of a device. In particular, the present disclosure relates to a frameless haptic feedback module that can be integrated with a device for moving and/or vibrating surfaces and components of the device.

### BACKGROUND OF THE INVENTION

Some hand held devices and gaming controllers employ conventional haptic feedback devices using small vibrators to enhance the user's gaming experience by providing force feedback vibration to the user while playing video games. A game that supports a particular vibrator can cause the device or gaming controller to vibrate in select situations, such as when firing a weapon or receiving damage to enhance the user's gaming experience. While such vibrators are adequate for delivering the sensation of large engines and explosions, they are quite monotonic and require a relatively high minimum output threshold. Accordingly, conventional vibrators cannot adequately reproduce finer vibrations or non-periodic motions that evoke specific haptic effects such as button clicks. Besides low vibration response bandwidth, additional limitations of conventional haptic feedback devices include bulkiness and heaviness when attached to a device such as a smartphone or gaming controller.

To overcome these and other challenges experienced with conventional haptic feedback devices, the present disclosure provides Electroactive Polymer Artificial Muscle (EPAM™) based frameless actuator modules comprising dielectric elastomers that have the bandwidth and the energy density required to make frameless haptic devices that are both responsive and compact. These frameless actuator modules may find use in a variety of applications, and are not limited to haptic feedback. Such EPAM™ based frameless haptic feedback modules comprise a thin sheet, which comprises a dielectric elastomer film sandwiched between two electrode layers. When a high voltage is applied to the electrodes, the two attracting electrodes compress the film thickness in the energized area. The EPAM™ based frameless actuator device provides a slim, low-powered actuator module that can be placed underneath an inertial mass (usually a battery or a touch surface) on a movable suspension to generate haptic feedback that can be perceived by the user.

### SUMMARY OF THE INVENTION

In one embodiment, a frameless actuator is provided. The frameless actuator comprises a frameless actuator comprising at least one elastomeric dielectric film disposed between first and second electrodes. A first pressure sensitive adhesive is applied on one side of the frameless actuator film. A second pressure sensitive adhesive is applied on an opposite side of the frameless actuator film.

### BRIEF DESCRIPTION OF THE FIGURES

The present invention will now be described for purposes of illustration and not limitation in conjunction with the figures, wherein:

FIG. 1 is a cutaway view of an actuator system, according to one embodiment.

FIG. 2 is a schematic diagram of one embodiment of an actuator system to illustrate the principle of operation.

FIG. 3 illustrates one embodiment of an actuator comprising a rigid frame and divider segments, similar to the actuator module shown in FIG. 1.

FIG. 4 shows one embodiment of an actuator without a frame structure, which is referred to herein as a frameless actuator.

FIG. 5 is a flow diagram of an installation process of one embodiment of a frameless two-layer (2L) actuator, similar to the frameless actuator shown in FIG. 4.

FIG. 6 is a flow diagram of a printing and assembly process for one embodiment of a two-layer frameless actuator film, such as the actuator film in accordance with the embodiment shown in FIGS. 4 and 5.

FIG. 7 shows a curved form-factor actuator module comprising a curved top plate, a curved bottom plate, and a frameless actuator slidably attached therebetween.

FIG. 8 is an exploded view of one embodiment of a frameless actuator.

FIGS. 9A, 9B, 9C, and 9D illustrate one embodiment of a process for constructing a two-layer (2L) actuator module with a disposable frame as shown in FIG. 11, below.

FIG. 10 illustrates one embodiment of a process for constructing one embodiment of a two-layer (2L) actuator module with a disposable pressure sensitive adhesive as shown in FIG. 12, below.

FIG. 11 is a side sectional view of one embodiment of a frameless actuator comprising a disposable frame.

FIG. 12 is a side sectional view of one embodiment of a frameless actuator comprising a pressure sensitive adhesive as the frame.

FIG. 13 is a set of one embodiment of printed frameless actuators comprising a multiple individual frameless actuators comprising a disposable frame.

FIG. 14 illustrates one embodiment of a singulated frameless actuator with the disposable frame still attached to hold the pre-strained film after singulation.

FIG. 15 shows one embodiment of a frameless actuator attached to a substrate and cut-out of the disposable frame.

FIG. 16 is a partial exploded view of one embodiment of a frameless actuator with a printed extended pressure sensitive adhesive surrounding the actuator film on three sides.

FIG. 17 shows one embodiment of a casing foil cut into nine separate units defining a pre cut outline.

FIG. 18 illustrates one embodiment of a casing foil comprising cut patterns designed to easily bind to the other part of the casing foil.

FIG. 19 shows the four-actuator film layers aligned onto the precut casing foil shown in FIG. 18 and ready for lamination by vacuum.

FIG. 20 shows the actuator films shown in FIG. 19 after the actuator films are cut and separated from the casing foil stretch frame.

FIG. 21 shows the casing foil shown in FIG. 19 with one remaining actuator film actuator left in the stretch frame.

FIG. 22 shows eight of the nine actuator film actuators removed from the casing foil stretch frame shown in FIG. 19.

FIG. 23 is a flow diagram of an installation process of one embodiment of a frameless actuator to a top plate and a bottom plate and compressed thereafter.

FIGS. 24A-24F illustrate various embodiments of a frameless actuator mounted on a curved surface.

FIGS. 25A and 25B illustrate one embodiment of a configurable actuator element.

FIG. 26 is one embodiment of an array of configurable actuator elements as shown in FIGS. 25A, 25B.

FIG. 27 is a graphical representation of inertial drive time response for various framed actuators and various embodiments of frameless actuators, according to the present disclosure.

FIG. 28 is a graphical representation of inertial drive frequency response for various framed actuators and various embodiments of frameless actuators, according to the present disclosure.

FIG. 29 is a graphical representation of inertial drive time response for various three-bar framed actuators and various embodiments of three-bar frameless actuators, according to the present disclosure.

FIG. 30 is a graphical representation of inertial drive frequency response for various three-bar framed actuators and various embodiments of three-bar frameless actuators, according to the present disclosure.

### DETAILED DESCRIPTION OF THE INVENTION

Before explaining the disclosed embodiments in detail, it should be noted that the disclosed embodiments are not limited in application or use to the details of construction and arrangement of parts illustrated in the accompanying drawings and description. The disclosed embodiments may be implemented or incorporated in other embodiments, variations and modifications, and may be practiced or carried out in various ways. Further, unless otherwise indicated, the terms and expressions employed herein have been chosen for the purpose of describing the illustrative embodiments for the convenience of the reader and are not for the purpose of limitation thereof. Further, it should be understood that any one or more of the disclosed embodiments, expressions of embodiments, and examples can be combined with any one or more of the other disclosed embodiments, expressions of embodiments, and examples, without limitation. Thus, the combination of an element disclosed in one embodiment and an element disclosed in another embodiment is considered to be within the scope of the present disclosure and appended claims.

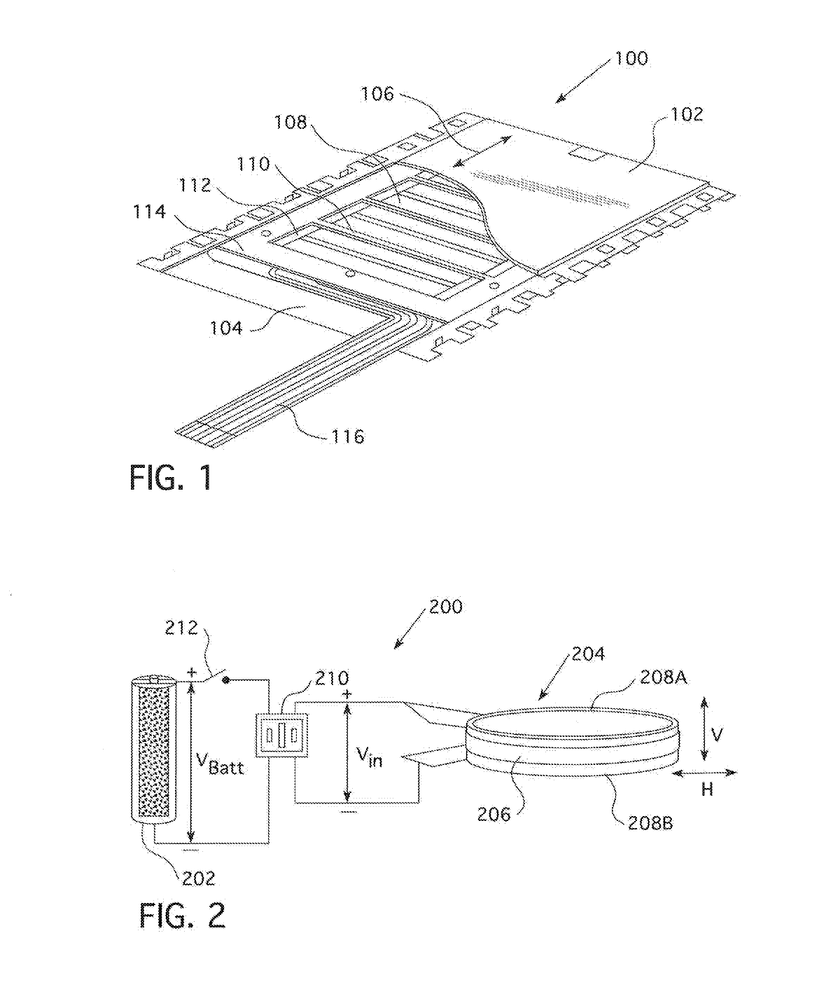

The present disclosure provides various embodiments of Electroactive Polymer Artificial Muscles (EPAM™) based frameless devices. Before launching into a description of various devices comprising EPAM™ based frameless actuator modules, the present disclosure briefly turns to FIG. 1, which is a cutaway view of a actuator system that may be integrally incorporated with hand held devices (e.g., devices, gaming controllers, consoles, and the like) to enhance the user's tactile feedback experience in a light weight compact module. Accordingly, one embodiment of an actuator system is now described with reference to a fixed plate type actuator module 100. An actuator slides an output plate 102 (e.g., sliding surface) relative to a fixed plate 104 (e.g., fixed surface) when energized by a high voltage. The plates 102, 104 are separated by steel balls, and have features that constrain movement to the desired direction, limit travel, and withstand drop tests. For integration into a device, the top plate 102 may be attached to an inertial mass such as the battery or the touch surface, screen, or display of the device. In the embodiment illustrated in FIG. 1, the top plate 102 of the actuator module 100 is comprised of a sliding surface that mounts to an inertial mass or back of a touch surface that can move bi-directionally as indicated by arrow 106. Between the output plate 102 and the fixed plate 104, the actuator module 100 comprises at least one electrode 108, at least one divider segment 110, and at least one bar 112 that attaches to the sliding surface, e.g., the top plate 102. A rigid frame 114 and the divider segments 110 attach to a fixed surface, e.g., the bottom plate 104. The actuator module 100 may comprise any number of bars 112 configured into arrays to amplify the motion of the sliding surface. The actuator module 100 may be coupled to the drive electronics of an actuator controller circuit via a flex cable 116.

Advantages of the EPAM™ based actuator module 10 include providing force feedback sensations to the user that are more realistic feelings, can be felt substantially immediately, consume significantly less battery life, and are suited for customizable design and performance options. The actuator module 100 is representative of actuator modules developed by Artificial Muscle Inc. (AMI), of Sunnyvale, Calif.

Still with reference to FIG. 1, many of the design variables of the actuator module 100, (e.g., thickness, footprint) may be fixed by the needs of module integrators while other variables (e.g., number of dielectric layers, operating voltage) may be constrained by cost. The allocation of footprint to rigid supporting structure versus active dielectric, actuator geometry, is a reasonable way to tailor performance of the actuator module 10 to an application where the actuator module 100 is integrated with a device.

Additional disclosure of haptic feedback modules integrated with the device for moving and/or vibrating surfaces and components of a device are described in commonly assigned and concurrently filed International PCT Patent Application No. PCT/US2012/______, filed on an even date herewith, entitled “FLEXURE APPARATUS, SYSTEM, AND METHOD,” the entire disclosure of which is hereby incorporated by reference.

FIG. 2 is a schematic diagram of one embodiment of a actuator system 200 to illustrate the principle of operation. The actuator system 200 comprises a power source 202, shown as a low voltage direct current (DC) battery, electrically coupled to an actuator module 204. The actuator module 204 comprises a thin elastomeric dielectric 206 disposed (e.g., sandwiched) between two conductive electrodes 208A, 208B. In one embodiment, the conductive electrodes 208A, 208B are stretchable (e.g., conformable) and may be printed on the top and bottom portions of the elastomeric dielectric 206 using any suitable techniques, such as, for example screen printing. The actuator module 204 is activated by coupling the battery 202 to an actuator circuit 210 by closing a switch 212. The actuator circuit 210 converts the low DC voltage V_{Batt} into a high DC voltage Vᵢₙ suitable for driving the actuator module 204. When the high voltage Vᵢₙ is applied to the conductive electrodes 208A, 208B the elastomeric dielectric 206 contracts in the vertical direction (V) and expands in the horizontal direction (H) under electrostatic pressure. The contraction and expansion of the elastomeric dielectric 206 can be harnessed as motion. The amount of motion or displacement is proportional to the input voltage Vᵢₙ. The motion or displacement may be amplified by a suitable configuration of actuator actuators as described in commonly assigned and concurrently filed International PCT Patent Application No. PCT/US2012/______, filed on an even date herewith, entitled “FLEXURE APPARATUS, SYSTEM, AND METHOD,” the entire disclosure of which is hereby incorporated by reference.

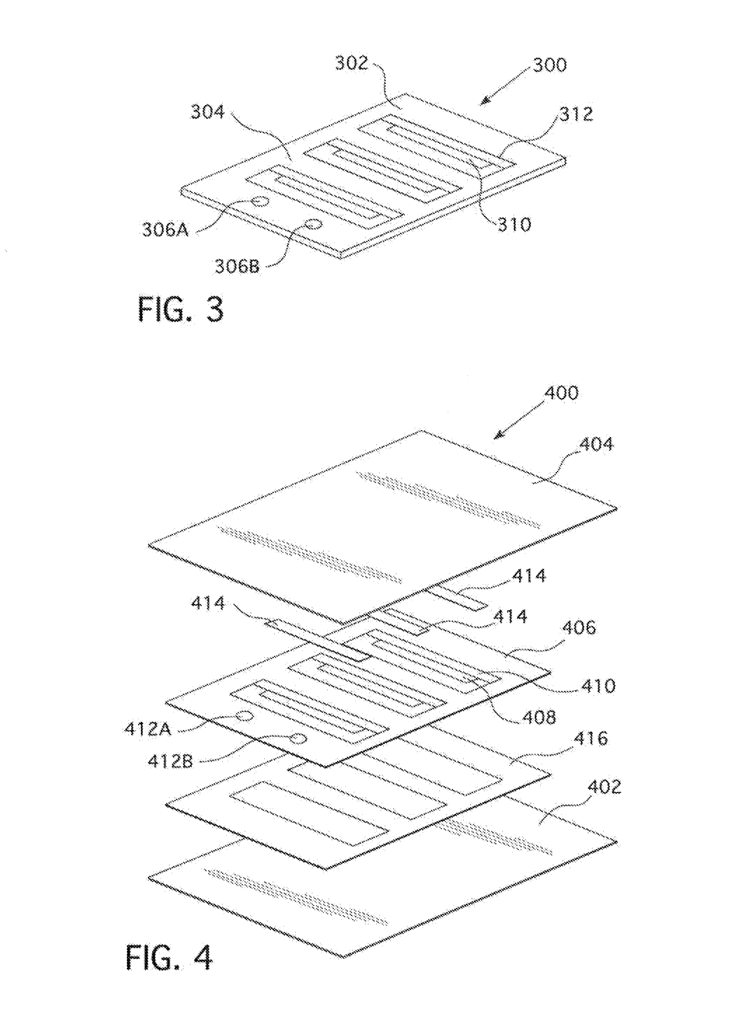

Various embodiments of frameless actuator modules are described in the present disclosure. FIG. 3 illustrates one embodiment of an actuator 300 comprising a rigid frame 302 and divider segments 304, similar to the actuator module 100 shown in FIG. 1. The actuator 300 is a three-bar actuator, for example, where each bar comprises an electrode 310 and an elastomeric dielectric 312 coupled to the rigid frame 302. It will be appreciated that the actuator 300 may comprise one or more bars depending on the level of mechanical amplification desired. The activation energy source is coupled to electrical input terminals 306A, 306B. The rigid frame 302 structure of the actuator 300 contributes to the overall thickness of the actuator 300. In various embodiments, the actuator 300 may have an overall thickness of about 400 μm±50 μm for a two layer device, and including installation pressure sensitive adhesive (PSA), the overall thickness is 500 μm±50 μm for a two layer device, where the thickness of the frame 302 may range from about 280 μm to about 320 μm, for example. Accordingly, to significantly reduce the overall thickness of the actuator 300, the frame 302 structure may be removed, since it is the primary contributor to the overall thickness of the actuator 300. One embodiment of an actuator without the frame structure 302 is referred to herein as a frameless actuator is shown in FIG. 4. A frameless actuator may be as thin as 200 μm for embodiments employing pressure sensitive adhesive.

FIG. 4 is an exploded view of one embodiment of a frameless actuator 400. The frameless actuator 400 comprises a first release liner 402 and a second release liner 404. An actuator film 406 is adhesively attached to the first and second release liners 402, 404 by way a first printed pressure sensitive adhesive 416 and a second printed pressure sensitive adhesive 414, respectively. In various embodiments, the actuator film 406 may comprise one or more layers. In one embodiment, the actuator film 406 may comprise two layers (2L) and in other embodiments, the actuator film 406 may comprise four layers (4L), without limitation. In the illustrated embodiment, the actuator film 406 comprises three-bars, where each bar 408 comprises an electrode 410, and an elastomeric dielectric 406, and input terminals 412A, 412B. Electrode is on both sides of the film although it could be a common ground (unpatterned) on one side. It will be appreciated that the actuator film 406 may comprise one or more actuator bars depending on the level of mechanical implication desired. In one embodiment, the actuator film 406 is pre-strained. Various methods of holding the pre-strained film 406 without having the film curl back during assembly are described hereinbelow. The release liners 402, 404 act as base layers for pressure sensitive materials and serve several purposes. Among those purposes, the release liners hold the pre-strained film using the adhesion of the pressure sensitive adhesive, and the liners protect an underlying adhesive layer until the actuator 400 is ready to be applied to a device. The release liners 402, 404 also should be easily removed when the actuator 400 is ready to be applied to a device. Accordingly, as discussed in more detail hereinbelow, the properties of the release liners 402, 404 and pressure sensitive adhesives 414, 416 should be balanced.

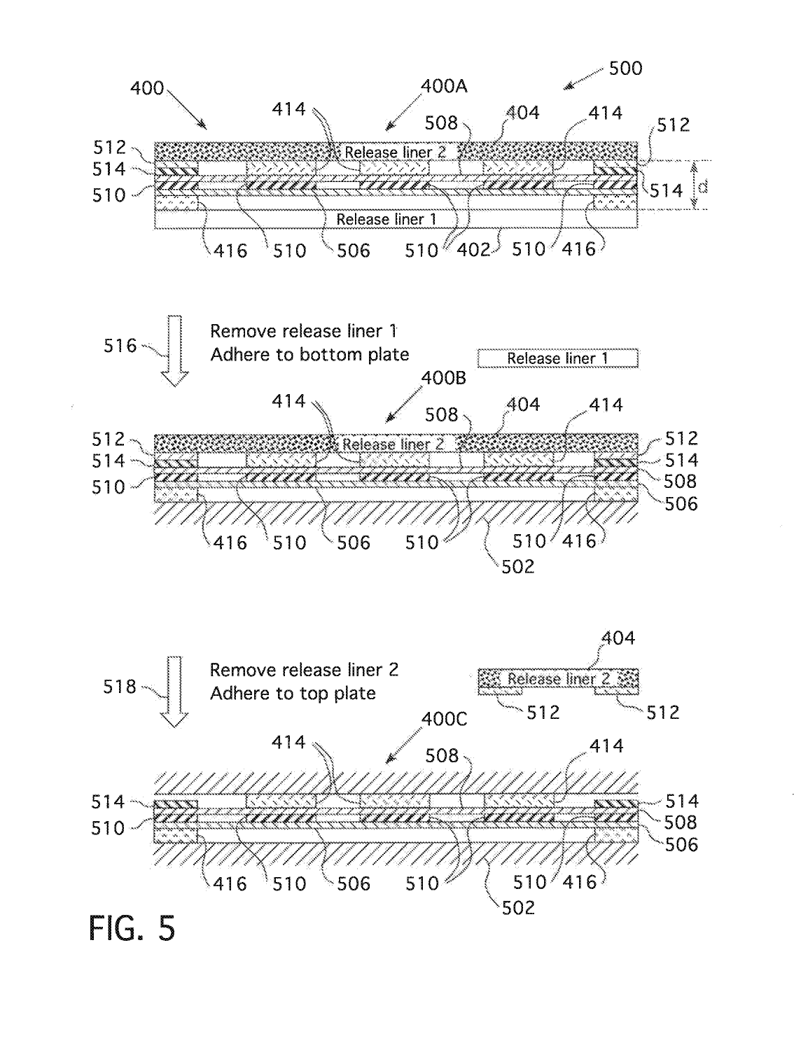

FIG. 5 is a flow diagram 500 of an installation process of one embodiment of a frameless two-layer (2L) actuator, similar to the frameless actuator 400 shown in FIG. 4. The frameless two-layer actuator is installed to a rigid frame comprising a top plate 504 and a bottom plate 502 to form an actuator module that can be coupled to the rigid top and bottom plates of a device. The actuator 400 is illustrated in three phases of installation by reference numbers 400A, 400B, 400C, where initially the frameless actuator 400A is provided with the first and second release liners 402, 404. The embodiment of the frameless actuator 400A illustrated in FIG. 5 is a pre-strained thin film type actuator 400A comprising the first release liner 402 and the second release liner 404. Pressure sensitive adhesive 414 releasably attaches the second release liner 404 to a first dielectric film 506 whereas the pressure sensitive adhesive 416 releasably attaches the first release liner 402 to a second dielectric film 508. Film-to-film adhesive 510 attaches the first dielectric film 506 to the second dielectric film 508. A removable pressure sensitive adhesive 512 is attached to the second release liner 404. A release layer 514 is attached to the first dielectric film 506. In the configuration shown in FIG. 5, the thickness “d” of the portion of the frameless two-layer (2L) actuator 400A between the first and second release liners 402, 404 is in a range of about 175 μm to about 215 μm.

In one embodiment, at process 516, the first release liner 402 is removed from the actuator 400A to provide actuator 400B, which is attached, e.g., adhered, to the bottom plate 502 by way of the pressure sensitive adhesive 416. Thus, the actuator 400B is fixedly coupled to the bottom plate 502.

Once the actuator 400B is fixedly coupled to the bottom plate 502, in one embodiment, at process 518 the second release liner 404 is removed from the actuator 400B to provide actuator 400C, which is attached, e.g., adhered, to the top plate 504. It is noted that the removable pressure sensitive adhesive 512 remains attached to the second release liner 404 when it is removed by proper selection of release energy, as discussed below. The actuator 400C now comprises the first dielectric film 506 adhesively attached to the bottom plate 502 and the second dielectric film 508 adhesively attached to the top plate 504. As previously discussed, the first and second dielectric films 506, 508 are adhesively coupled by way of the film-to-film adhesive 510. The release layer 514 remains attached to the one side of the second dielectric film 508 opposite an inner wall portion of the top plate 504.

It will be appreciated that the release energies of the various pressure sensitive adhesives, removable pressure sensitive adhesives, first and second release liners, and release layer is selected as follows, in accordance with one embodiment. The release energy of the pressure sensitive adhesive 416/first release liner 402 interface is less than the release energy of the removable pressure sensitive adhesive 512/release layer 514 interface, which is less than the release energy of the second release liner 404/pressure sensitive adhesive 414 interface, which has approximately the same release energy as the second release liner 404/removable pressure sensitive adhesive 512 interface. TABLE 1 provides release energy data for various combinations of release surface and adhesive interfaces. TABLE 2 provides peel force data for various combinations of substrates and adhesive interfaces.

TABLE 1
Release Energy Data

| | Adhesives | | | | | | | | | | | | |
|---|---|---|---|---|---|---|---|---|---|---|---|---|---|
| | | DC2013 | | 529 | | 6573A | | SP7514 | | SP7555 | | 186-02 | |
| | | Ave. | Stdev. | Ave. | Stdev. | Ave. | Stdev. | Ave. | Stdev. | Ave | Stdev. | Ave. | Stdev. |
| Release Surface | F.S. PET | 0.2 | 0.06 | | | | | | | | | | |
| (N/100 ml) | (1.5 mil) | | | | | | | | | | | | |
| | 7526 L matte | 0.2 | 0.6 | | | | | | | | | | |
| | (4.3 mil) | | | | | | | | | | | | |
| | 7526 L gloss | 0.3 | 0.1 | | | | | | | | | | |
| | (4.3 mil) | | | | | | | | | | | | |
| | White Wax | | | | | | | 14.0 | 2.8 | 22.5 | 5.4 | 0.06 | 0.03 |
| | Paper | | | | | | | | | | | | |
| | (5 mil) | | | | | | | | | | | | |
| | Coated PET | 10.9 | 1.2 | | | | | 13.2 | 2.5 | 9.7 | 4.0 | 0.01 | |
| | (2 mil) | | | | | | | | | | | | |
| | PET (2 mil) | | | | | | | | | | | 0.05 | |
| | PE (SR50) | | | | | | | | | | | 0.2 | 0.1 |
| | (2 mil) | | | | | | | | | | | | |
| | Mylan 2114 | 1.6 | 0.7 | | | 0.3 | 0.06 | | | | | | |
| | (silicone) | | | | | | | | | | | | |
| | Mylan 2119 | 7.9 | 3.7 | | | 1.0 | 0.3 | | | | | | |
| | (silicone) | | | | | | | | | | | | |
| | Mylan 2500 | 0.4 | 0.1 | 0.3 | 0.05 | 0.2 | 0.05 | | | | | | |
| | (f.s.) | | | | | | | | | | | | |
| | Trennpapier | 9.6 | 2.3 | | | | | | | | | | |
| | (p.olefin) | | | | | | | | | | | | |
| | RL1 | >10.9 | | | | | | 3.2 | 1.8 | 6.9 | 1.9 | | |

TABLE 2
Peel Force Data

| | Adhesives | | | | | | |
|---|---|---|---|---|---|---|---|
| | | DC2013 | | 529 | | 6573A | |
| | | Ave. | Stdev. | Ave. | Stdev. | Ave. | Stdev. |
| Release | ABS | 11.4 | 1.3 | 22.0 | 4.7 | 8.9 | 1.9 |
| Surface | Polished | 10.0 | 1.3 | 14.0 | 1.7 | 38.4 | 0.3 |
| (N/100 ml) | Stainless | | | | | | |
| | Steel | | | | | | |

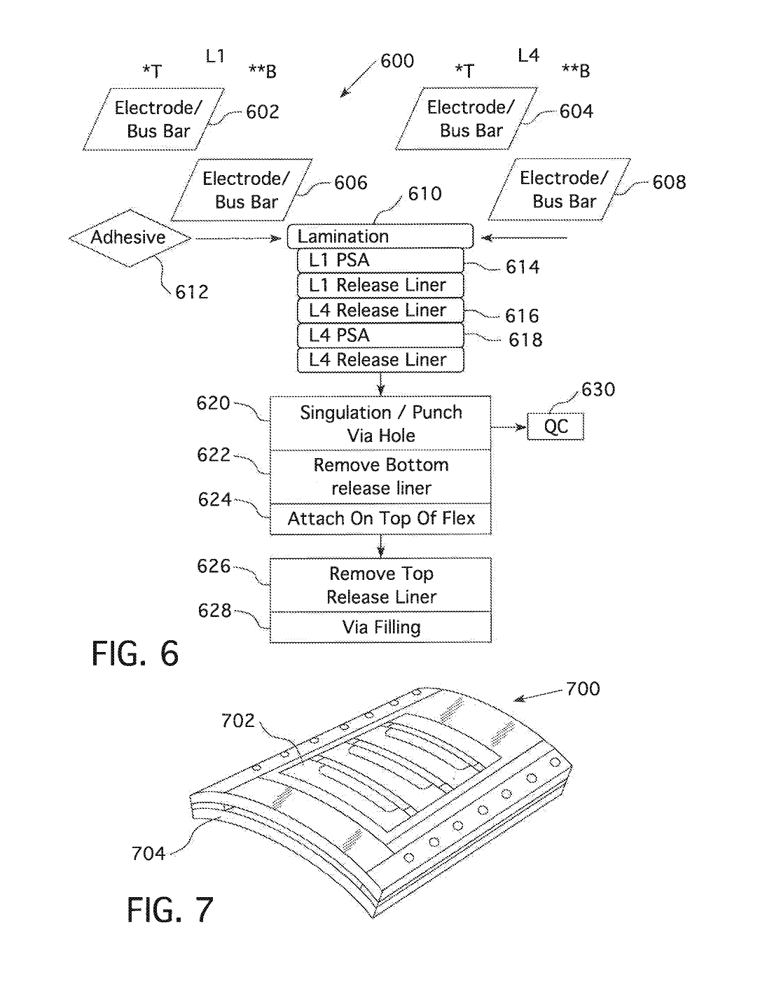

FIG. 6 is a flow diagram 600 of a printing and assembly process for one embodiment of a two-layer frameless actuator film, such as the actuator film 406 in accordance with the embodiment shown in FIGS. 4 and 5. As shown in FIG. 6, first and second dielectric film layers (L1), (L4) each comprise a top side *T and a bottom side **B. An electrode/bus bar 602 is printed on a top side *T of the first dielectric film layer (L1) and an electrode/bus bar 604 is printed on a top side *T of the second dielectric film layer (L4). An electrode/bus bar 606 is printed on a bottom side **B of the first dielectric film layer (L1) and an electrode/bus bar 608 is printed on a bottom side **B of the second dielectric film layer (L4). In one embodiment, the first dielectric film layer (L1) is laminated to the second dielectric film layer (L4) with the film-to-film adhesive 612. In other words, the top side *T of the first dielectric film layer (L1) is adhesively attached to the top side *T of the second dielectric film layer (L4) with the film-to-film adhesive 612. Additional layers are now laminated on the first and second dielectric film layers (L1), (L4). A pressure sensitive adhesive (L1 PSA) is applied 614 to the bottom side **B of the first dielectric film layer (L1) and a release liner is laminated to L1 PSA (614). A release layer (L4 R.L.) is applied 616 to the bottom side of the second dielectric film layer (L4). A pressure sensitive adhesive (L4 PSA) is applied 618 to the bottom side **B of the second dielectric film layer (L4) and also to the top of release layer (L4 R.L.) 616. A release liner is laminated to L4 PSA, 618. The laminated actuator film structure is singulated 620 by die cutting, for example. At least one via hole can be punched at the same time that the laminated actuator film structure is singulated 620. Quality control (QC) of actuator can be done after singulation/via hole punch.

The singulated laminated actuator film structure can now be attached to a device. To attach the singulated laminated actuator film structure, the bottom release liner is removed 622 and attached 624 on top of the device. The top release liner is removed 626 and the at least one via can be filled 628.

TABLE 3 provides performance data for a 3-bar frameless actuator.

TABLE 3
Three-Bar Frameless Actuator Performance Data

| | Pulse | | | | | |
|---|---|---|---|---|---|---|
| | Response | Stroke | Stroke @ | Resonant | | |
| | @ 75 Hz | @ 1Hz | Resonance | Frequency | Manufacturing/ | |
| | (um) | (um) | (um) | (Hz) | Assembly Methods | Note |
| FCE1007- | 112 | 54 | 192 | 83 | Linerless, no ripstop | |
| 1011 | | | | | | |
| Apr. 25, 2011 | 118 | 62 | 186 | 86 | Linerless, no ripstop, | |
| | | | | | No printed bottom | |
| | | | | | PSA, closed fixture | |
| HNM1337- | 123 | 60 | 200 | 81 | Linerless | |
| 1339 | | | | | | |
| MKY1143- | 130 | 73 | 201 | 82 | Linerless, ABS, AI | |
| 1143 | | | | | bottom plates with | |
| | | | | | embedded flex | |
| JM1137 | 133 | 65 | 215 | 73 | | 4 L |
| MKY1183- | 150 | 84 | 225 | 67 | | 4 L |
| 1185 | | | | | | |

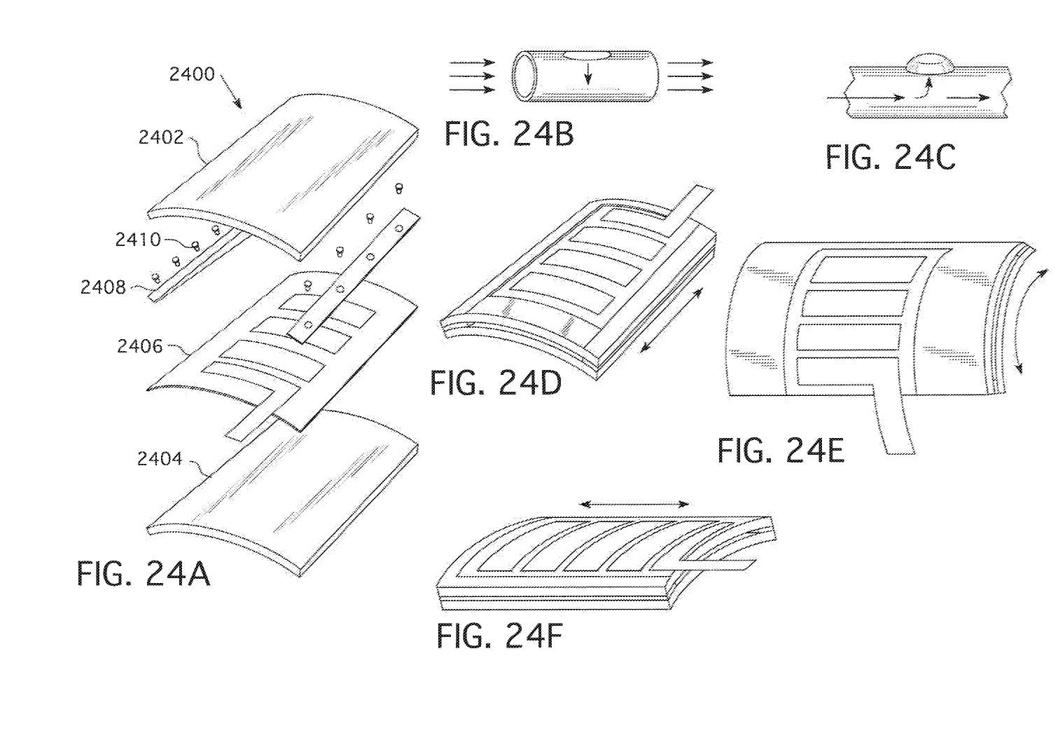

Those skilled in the art will appreciate that frameless actuator configurations as described herein provide a variety of benefits and advantages relative to framed actuator configurations. Such advantages include decrease in the overall thickness of the actuator module. For example, a two layer (2L) frameless actuator may be realized with a two-layer thickness of about 175 μm to about 215 μm and an overall thickness of about 500 μm for a actuator module. For example, a four layer (4L) frameless actuator may be realized with a four-layer thickness of about 275 μm to about 315 μm and an overall thickness of about 700 μm for a actuator module. By comparison, the thickness of framed actuators and modules would be about 500 to 600 μm and about 0.9 to 1.1 mm, respectively. In addition, the frameless actuator designs can potentially decrease material and manufacturing costs for die-cut pressure sensitive adhesives applied manually. Frameless actuators can be formed by non-contact printing and can be transparent with transparent electrodes and buss bars. Additional advantages of frameless actuators, as shown in FIG. 7, include conformability and flexibility for curved form-factor actuator modules 700. As shown in FIG. 7, the curved form-factor actuator module 700 comprises a curved top plate 702, a curved bottom plate 704, and a frameless actuator 706 slidably attached therebetween. Additional embodiments of frameless actuators mounted on curved surfaces are described in connection with FIGS. 24A-24F.

Furthermore, in other embodiments, an actuator module without a frame is provided to reduce the overall thickness. The actuator module comprises a frame (or liner) that is completely disposable. For example, if the adhesive is printed in the pattern of the output bars on one side of the actuator film and in the pattern of the frame on the other side of the actuator film, the film may be attached to a surface of a fixed substrate in a device, e.g., the back of a backlight and a housing of the unit, and finally cut away the disposable frame. In one embodiment, the method comprises pre-stretching or pre-straining the actuator film; printing windows in a ripstop or joining the actuator film to a temporary “frame” material strong enough to support the pre-strain after singulation; printing electrodes and bus bars; printing adhesive as described above; adding release liners; and singulating the actuators.

For single layer devices, the perimeter of the actuator film could be fully adhered to one of the rigid surfaces of a substrate. For multiple layers, a stronger film-to-film adhesive may need to be printed to better support the load. As a variation, a disposable frame could be printed on only one side of the actuator film. This may be, for example, the side with the output bars, since that would have less support from the rigid surfaces of the substrate to support the pre-strain. Such techniques would reduce the overall thickness of the actuator module. Additional techniques include using film-to-film adhesives, making vias/interconnections, selectively curing regions of adhesives to make them more rigid to create an intrinsic frame, imbibing reactive material in the appropriate places and then curing them up.

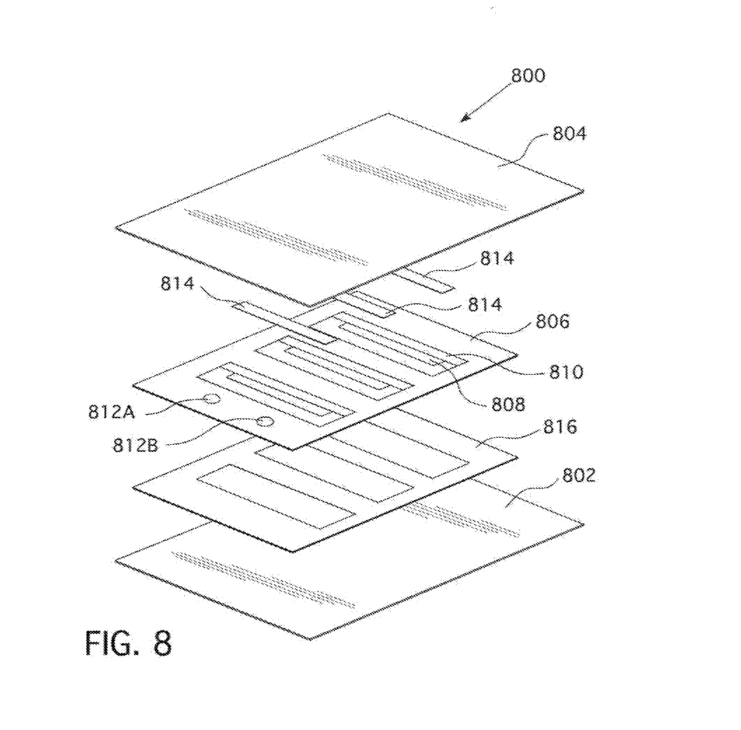

FIG. 8 is an exploded view of one embodiment of a frameless actuator 800. The frameless actuator 800 comprises a first release liner 802 and a second release liner 804. An actuator film 806 is adhesively attached to the first and second release liners 802, 804 by way a first printed pressure sensitive adhesive 816 and a second printed pressure sensitive adhesive 814, respectively. A disposable frame 818 is formed around the actuator film 806. Alternatively, in one embodiment, the disposable frame 818 may be replaced with a pressure sensitive adhesive to perform the same function as the disposable frame 818. In various embodiments, the actuator film 806 may comprise one or more layers. In one embodiment, the actuator film 806 may comprise two layers (2L) and in other embodiments, the actuator film 806 may comprise four layers (4L), without limitation. In the illustrated embodiment, the actuator film 806 comprises three-bars, where each bar 808 comprises an electrode 810, and an elastomeric dielectric 806, and input terminals 812A, 812B. It will be appreciated that the actuator film 806 may comprise one or more actuator bars depending on the level of mechanical performance desired. In one embodiment, the actuator film 806 is pre-strained. Various methods of holding the pre-strained film 806 without having the film curl back during assembly are described hereinbelow. The release liners 802, 804 act as base layers for pressure sensitive materials and serve several purposes. Among those purposes, the release liners hold the pre-strained film using the adhesion of the pressure sensitive adhesive, and the liners protect an underlying adhesive layer until the actuator 800 is ready to be applied to a device. The release liners 802, 804 also should be easily removed when the actuator 800 is ready to be applied to a device. Accordingly, as discussed in more detail hereinbelow, the properties of the release liners 802, 804 and pressure sensitive adhesives 814, 816 should be balanced.

The disposable frame 818 may be employed to hold or support a pre-stretched actuator film 806 before it is attached to a rigid substrate. In one embodiment, the disposable frame 818 material outside of the actuator film 806 area is disposable. Accordingly, after the frameless actuator 800 is attached to a desired cartridge, the disposable frame 818 can be cut out and discarded. In one embodiment, the disposable frame 818 layers may be required to hold an actuator film 806. The disposable frame 818 can be printed as a ripstop and one or more frames 818 may be formed on the opposite side of the actuator film 806. If additional stiffness is required, for a particular application, it may be desirable to replace the adhesive layer 816 with a frame material.

A die-cut polyethylene terephthalate (PET) material may be employed as the disposable frame 818. In one embodiment, the disposable frame 818 may be needed only on an output bar side. The opposite side to disposable frame 818 pattern side (bottom side) can be attached on a substrate first and then the disposable frame 818 can be cut out. In one embodiment, the pressure sensitive adhesive may be extended printed around the actuator film 806 to perform the same function of the disposable frame 818. In one embodiment, a pressure sensitive adhesive can be extended printed on an output bar disposable area to support a pre-strained film to form a disposable frame. The release liners 802, 804 can be attached on both sides of the actuator 800 and die-cut for singulation. A printed extended pressure sensitive adhesive disposable frame 818 area formed on the top output bar side can support a pre-strained film of the singulated actuator 800 cartridge after removing the release liners 802 on the bottom sides. After attaching the bottom side of the actuator 800 to a substrate, the disposable pressure sensitive adhesive disposable frame 818 can be cut out. In one embodiment, a silicone pressure sensitive adhesive disposable frame 818 would be suitable for holding a pre-strained actuator film 806 substrates for long-term cycles. Preliminary testing shows that silicone pressure sensitive adhesives have good adhesion for frame-pattern pressure sensitive adhesive applications after 65° C./85% testing. A stronger pressure sensitive adhesive than silicone such as an acrylic type pressure sensitive adhesive may be used for printing output bar patterns. Because acrylic does not have good adhesion to silicone film, one print of frame material for the output bar can be used as intermediate tie layer.

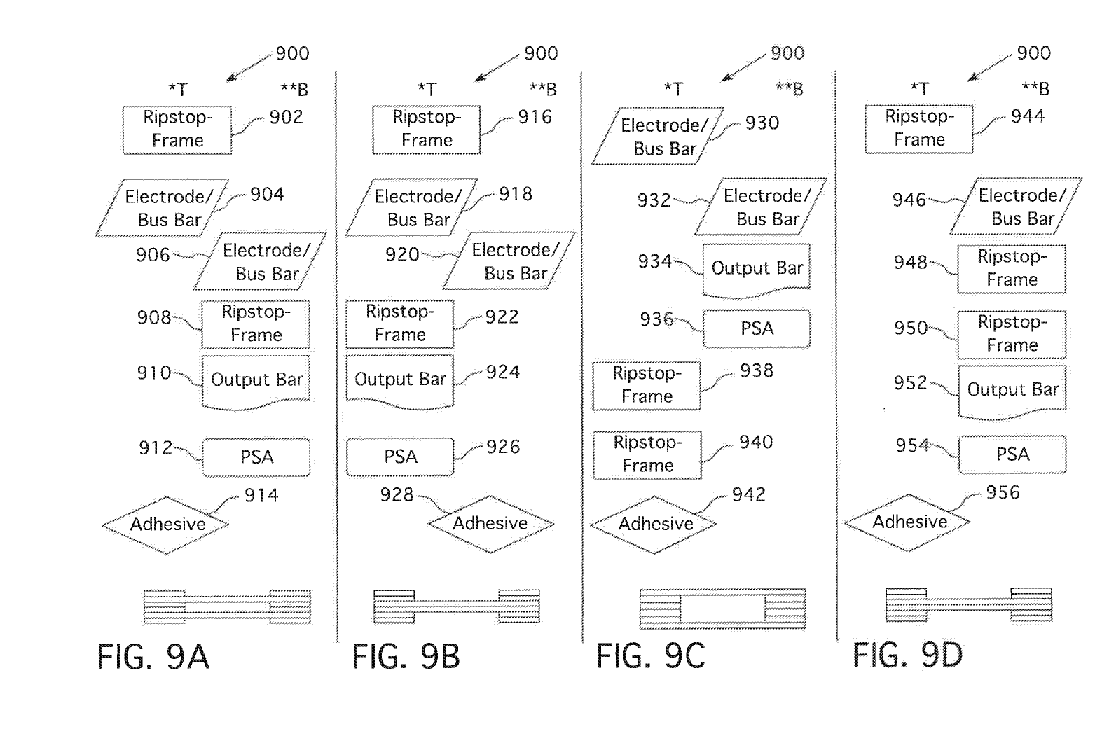

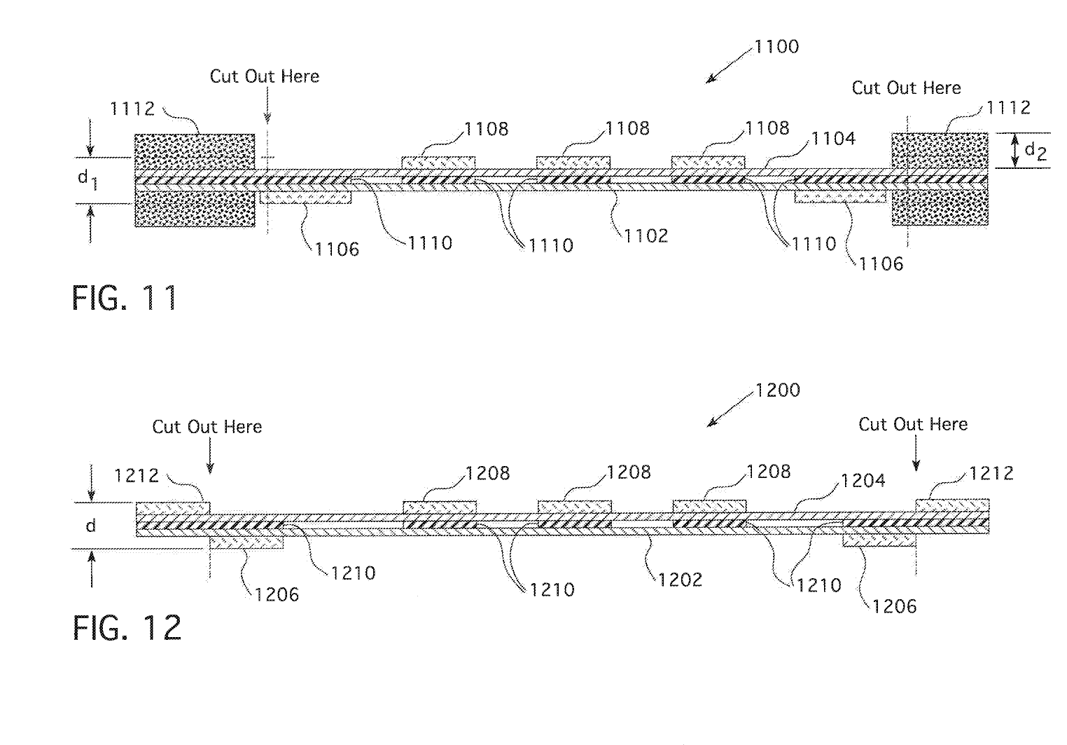

FIGS. 9A, 9B, 9C, and 9D illustrate one embodiment of a process 900 for constructing one embodiment of a two-layer (2L) actuator module 1100 with a disposable frame as shown in FIG. 11. The FIGS. 9A, 9B, 9C, and 9D illustrate only the L4 layer of a two-layer (2L) actuator module. In FIG. 9A one embodiment of a first dielectric film is provided, where the first dielectric film has a top side *T and a bottom side **B. A first ripstop fabric frame is applied 902 to the top side *T of the dielectric film. It will be appreciated that a ripstop fabric is a woven fabric that can be made of nylon using a reinforcing technique making the fabric resistant to tearing and ripping. An electrode/bus bar is printed 904 on the top side *T of the dielectric film. An electrode/bus bar is printed on the bottom side **B of the dielectric film. A second ripstop frame is applied 908 to the bottom side **B of the dielectric film and an output bar is printed 910 on the bottom side **B of the dielectric film. A pressure sensitive adhesive is printed on the bottom side **B of the dielectric film. An adhesive layer is applied 914 on the top side **T of the dielectric film and laminated with another dielectric film.

In FIG. 9B another ripstop frame is applied 916 to the top side *T of the first dielectric film. An electrode/bus bar is printed 918 on the top side *T of the first dielectric film. An electrode/bus bar is printed 920 on the second side **B the first dielectric film. Another ripstop frame is provided and applied 922 to the top side *T of the first dielectric film. An output bar is printed 924 on the top side *T of the first dielectric film. A pressure sensitive adhesive is printed 926 on the top side *T of the dielectric film. An adhesive layer is applied 928 to the bottom side **B of the first dielectric film.

In FIG. 9C a dielectric film is provided, where the dielectric film has a top side *T and a bottom side **B. An electrode/bus bar is printed 930 on the top side *T of the dielectric film layer. An electrode/bus is then printed 932 on the bottom side **B of the dielectric film layer. An output bar is then printed 934 on the bottom side space**B of the dielectric film layer. A pressure sensitive adhesive is then printed 936 on the bottom side **B of the second dielectric film layer. A ripstop frame is applied 938 on the top side space*T of the dielectric film layer. Another ripstop frame is applied 940 on top of the previous ripstop frame. An adhesive layer is applied 942 to the top side*T of the dielectric film layer.

In FIG. 9D an electrode/bus bar is printed 944 on the top side *T of the dielectric film layer. An electrode/bus is printed 946 on the bottom side **B of the dielectric film layer. A ripstop frame is applied 948 to the bottom side of the dielectric film layer and another ripstop frame is applied 950 above the previous ripstop frame. An output bar is then printed 952 on the bottom side **B of the dielectric film layer. A pressure sensitive adhesive is applied 950 on the bottom side **B of the dielectric film layer. An adhesive layer is then applied 956 to the top side *T of the dielectric film layer.

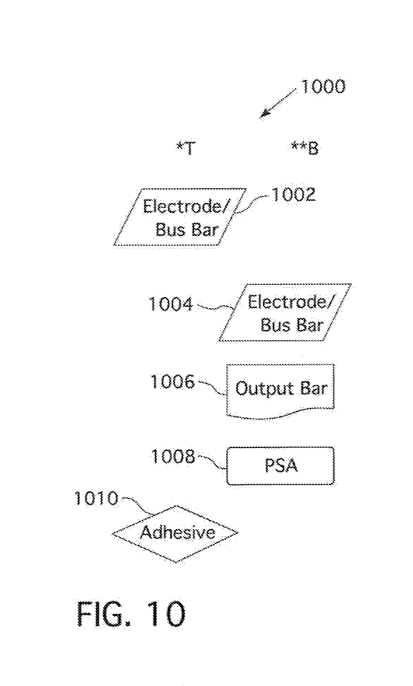

FIG. 10 illustrates one embodiment of a process 1000 for constructing one embodiment of a two-payer (2L) actuator module 1200 with a disposable pressure sensitive adhesive as shown in FIG. 12. The FIG. 10 illustrates only the L4 layer of a two-layer (2L) actuator module. In FIG. 10, a dielectric film is provided, where the first dielectric film is a top side *T and a bottom side **B. An electrode/bus bar is printed 1002 on the top side space*T of the dielectric film. An electrode/bus bar is printed 1004 on the bottom side **B of the dielectric film. An output bar is then printed 1006 on the bottom side **B of the dielectric film. A pressure sensitive adhesive is then printed 1008 on the bottom side **B of the dielectric film. An adhesive layer is then applied 1010 to the top side *T of the dielectric film layer.

FIG. 11 is a side sectional view of one embodiment of a frameless actuator 1100 comprising a disposable frame 1112. First and second dielectric films 1102, 1104 are laminated using a film-to-film adhesive 1110. A first pressure sensitive adhesive 1106 is printed on a bottom side of the first dielectric film 1102 and a second pressure sensitive adhesive 1108 is printed on a top side of the second dielectric film 1104. The frameless actuator 1100 structure is supported in a pre-stretched configuration by disposable frame 1112 surrounding the frameless actuator 1100 structure. The thickness of the frameless actuator 1100 structure “d₁” is about 177 μm, where the pressure sensitive adhesive layers 1106, 1108 are about 50 μm thick, the first and second dielectric films 1102, 1104 are each about 25 μm thick, and the film-to-film adhesive 1110 is about 27 μm thick. The thickness of the disposable frame “d₂” is about 140 μm. The frameless actuator 1100 structure is cut out from the disposable frame 1112, singulated, where indicated by the arrows labeled “Cut Out Here.”

FIG. 12 is a side sectional view of one embodiment of a frameless actuator 1200 comprising a pressure sensitive adhesive as the frame. First and second dielectric films 1202, 1204 are laminated using a film-to-film adhesive 1210. A first pressure sensitive adhesive 1206 is printed on a bottom side of the first dielectric film 1202 and a second pressure sensitive adhesive 1208 is printed on a top side of the second dielectric film 1204. The frameless actuator 1200 structure is supported in a pre-stretched configuration by the pressure sensitive adhesive frame 1212 surrounding the frameless actuator 1200 structure. It will be appreciated that the pressure sensitive adhesive frame 1212 is formed of the pressure sensitive adhesive 1208. The thickness of the frameless actuator 1200 structure “d” is about 177 μm, where the pressure sensitive adhesive layers 1206, 1208 are about 50 μm thick, the first and second dielectric films 1202, 1204 are each about 25 μm thick, and the film-to-film adhesive 1210 is about 27 μm thick. The frameless actuator 1200 structure is cut out, singulated, from the pressure sensitive adhesive frame 1212 where indicated by the arrows labeled “Cut Out Here.”

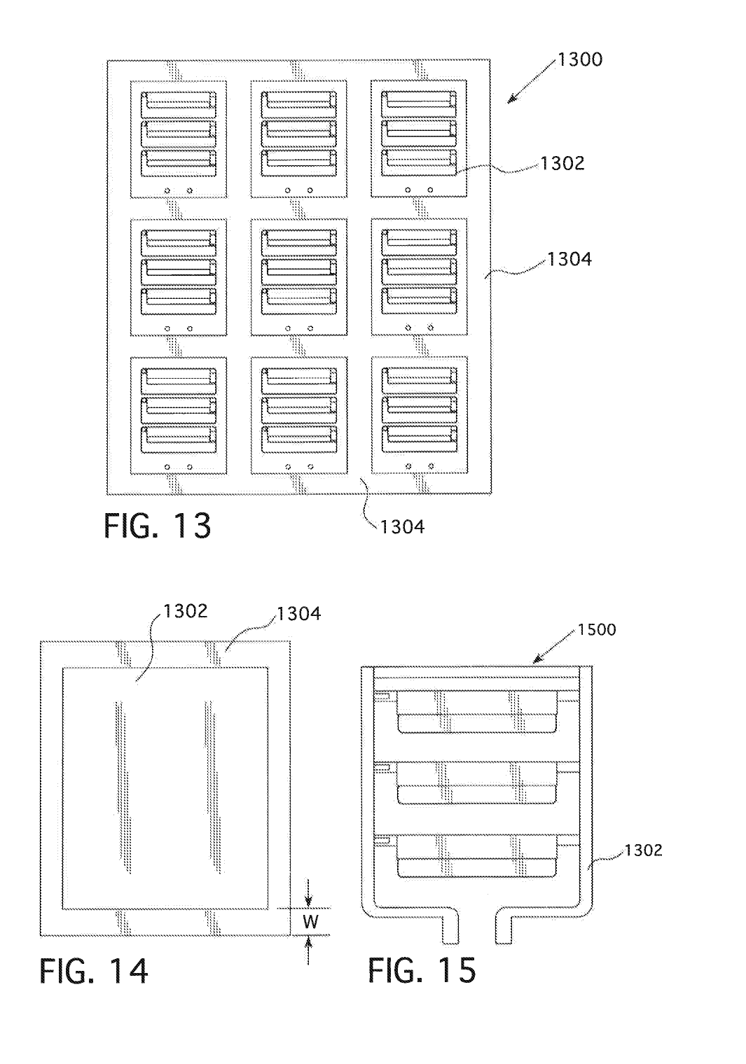

FIG. 13 is one embodiment of printed frameless actuators 1300 comprising a multiple individual frameless actuators 1302 comprising a disposable frame 1304. The frameless actuators 1302 are similar to those previously discussed in connection with FIGS. 8 and 11 and fabricated using the process described in connection with FIGS. 9A-D. Although nine actuators 1302 are shown in FIG. 13, any suitable number of actuators 1302 may be printed as practical. For example, one or more actuators 1302 can be printed using the process described in connection with FIGS. 9A-D.

FIG. 14 illustrates one embodiment of a singulated frameless actuator 1302 with the disposable frame 1304 still attached to hold the pre-strained film after singulation. In one embodiment, a disposable frame 1304 having a width “w” of at least 5 mm is sufficient to hold the pre-strained film after singulation.

FIG. 15 shows one embodiment of a frameless actuator 1302 attached to a substrate 1500 and cut-out of the disposable frame 1304.

During assembly of frameless actuators, dielectric films tend to lift up and adhere or stick to the bottom plate after pressure is applied, which makes it difficult to lift up the output bars. A top plate having a protruded output bar helps when it is applied first and then the bottom frame part is applied to the substrate. A fixture may be employed to push out the films surrounding the output bar for multi-bar design (e.g., three-bar designs). A spacer can also be used. A via interconnection may be formed by making a hole, filling the via material at the thickness of the dielectric films, and removing the release liners without distorting the via material. In one embodiment, the via hole may be made with a hole punch or staple and filled with hot melt adhesive. The hole punch or staple makes the hole through the film and the hot melt will be deposited into the via hole. The hole punch or staple should have a bottom fixture having a thickness of the bottom release liner such that it just deposits the hot-melt to the thickness of the dielectric film. An anisotropic conductive adhesive may be employed to make an electrical connection from the via hole to the flex circuit.

It will be appreciated that alternative processes, materials, and design modifications may be made without departing from the scope of the frameless actuator according to the present disclosure. For example, in one embodiment, a stiffer material may be employed as an adhesive making the frameless actuator easier to assemble. In another embodiment, a stronger bottom pressure sensitive adhesive may be employed for the output bar without epoxy. In yet another embodiment of the fabrication process, the lamination process may be conducted prior to printing the pressure sensitive adhesives to avoid over curing of the top pressure sensitive adhesive. In one embodiment, the top pressure sensitive adhesive is thermal curable and the bottom pressure sensitive adhesive is ultra-violet (UV) curable. In yet another embodiment, a color may be employed for the top pressure sensitive adhesive to make it easy to recognize the top side from the bottom side. With extended pressure sensitive adhesive designs where the pressure sensitive adhesive is used as a frame surrounding the actuator film, if a flex circuit is needed, the extended pressure sensitive adhesive on the flex circuit region is not printed so that attachment of the frameless actuator to the flex circuit and cut-out of the extended pressure sensitive adhesive do not pose any issues.

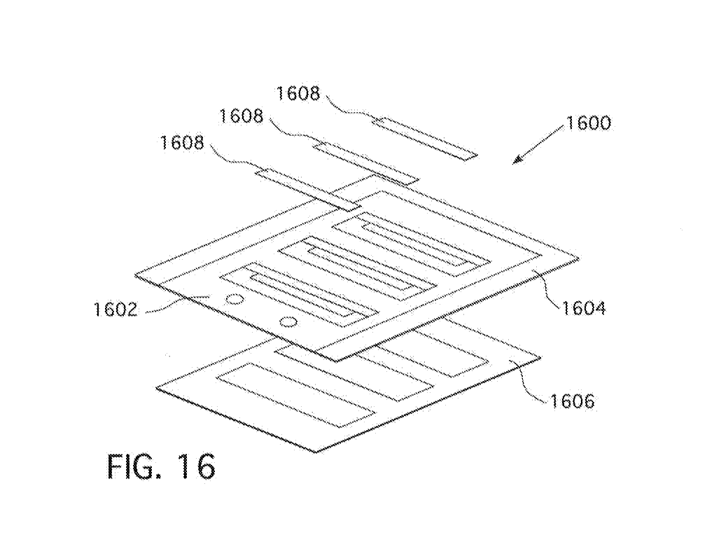

FIG. 16 is a partial exploded view of one embodiment of a frameless actuator 1600 with a printed extended pressure sensitive adhesive 1604 surrounding the actuator film 1602 on three sides. The extended pressure sensitive adhesive 1604 on three sides still helps to hold the actuator film 1602 to the release liners with pressure sensitive adhesives 1606 and 1608 printed on both sides on the actuator film 1602.

As previously discussed, for EPAM based actuator modules to be incorporated with devices, consideration is given to the overall thickness of the actuator module. For example, a two-layer, three-bar actuator may be as thick as 500 μm. Reduction of the overall thickness of a actuator module includes reduction of the frame thickness or elimination of the frame from the design in favor of a frameless actuator as described herein. Flexible, frameless laminated film based actuators, however, are more challenging to place onto a substrate because the laminated films have been stretched up to 30%.

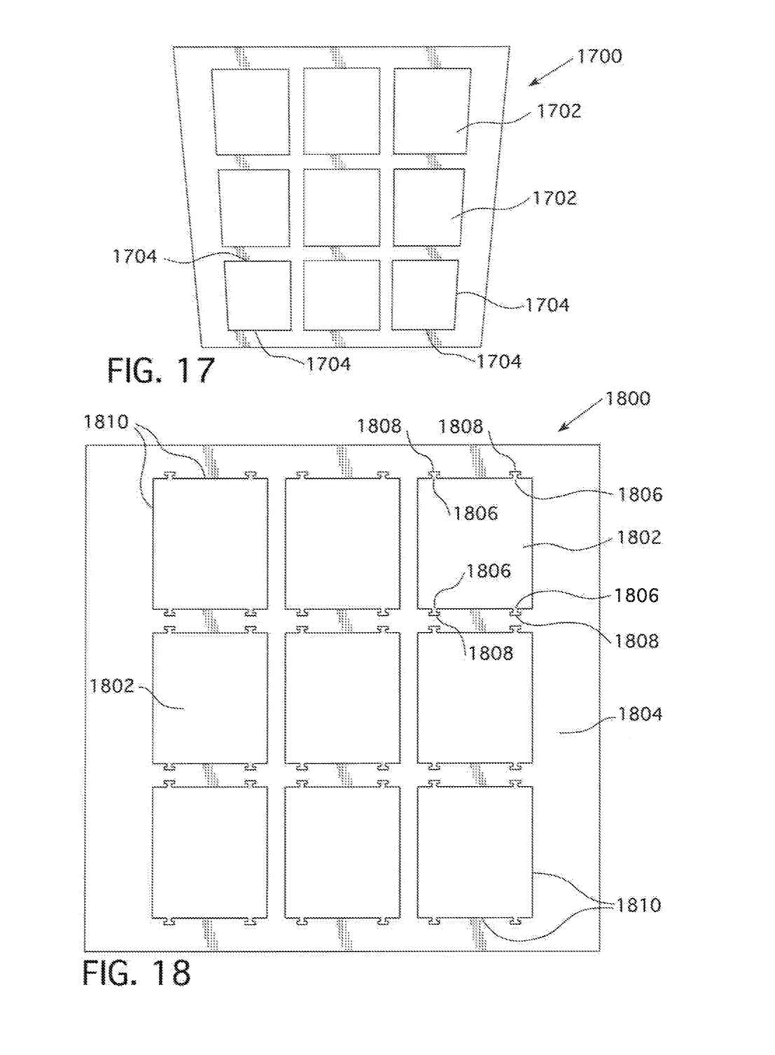

FIGS. 17-21 are used to describe a method for placing the laminated EPAM frameless actuator films in a casing foil with singulation. The method also combines lamination, singulation, and casing in one process. Quality control can be done at the casing the level. In one general respect, in accordance with the method, laminate all the layers of the films onto a foil of a casing, such as stainless steel foil or aluminum foil. Preprinted adhesive may be applied onto the films to combine each layer of the films together and also to bind the bottom layer of the film to the casing. The casing can hold each frameless actuator cartridge after the films are separated from the stretch frame.

Two methods are provided for performing the singulation process. In one embodiment, an entire casing foil is prepared in size similar to the stretch frame and the casing foil is precut into multiple units in size of the final frameless actuator. The casing foil components may be held together on the original location by friction or a polymer film with a release agent coating. FIG. 17 shows one embodiment of a casing foil 1700 cut into nine separate units 1702 defining a pre-cut outline 1704. In one embodiment, each unit may be about 36 mm×about 42 mm in size. The casing foil 1700 is now ready for the lamination process as described hereinbelow. After the lamination process, mechanical stamping, diamond sawing, or blade, laser, or water jet cutting can be used to singulate the individual films formed on each unit 1702.

In another embodiment, the entire size of the casing foil can be used for lamination, which is similar in size to the stretch frame. In accordance with this method, the casing is not cut into individual actuator units until the lamination process is completed. After the lamination process is completed, similar cutting methods can be used to singulate the individual units to cut the lamination films into separate units of frameless actuators, with the metal foil of the casing cut at the same time. The cutting methods comprise mechanical stamping, diamond sawing, or blade, laser or water jet cutting. Although this embodiment provides a simpler process, it also depends on selecting a cutting method that is compatible with the actuator film components to prevent destroying them in the process. For example, the mechanical forces, debris, and heat generated during the process should not damage or impair the frameless actuator components.

FIG. 18 illustrates one embodiment of a casing foil 1800 comprising cut patterns 1802 designed to easily bind to the other part of the casing foil 1800. The casing foil 1800 shown in FIG. 18 can be used with either embodiment of the singulation process described above. In the illustrated embodiment, the casing foil 1800 comprises a frame 1804 to support the cut patterns 1802 defining a precut outline 1810. The cut patterns comprise male protruding members 1806 having a shape and geometry to easily bind with the frame 1804 portion of the casing foil 1800. For example, the male protruding members 1806 are configured to interlock with corresponding female members 1808 formed in the frame 1804 of the casing foil 1800.

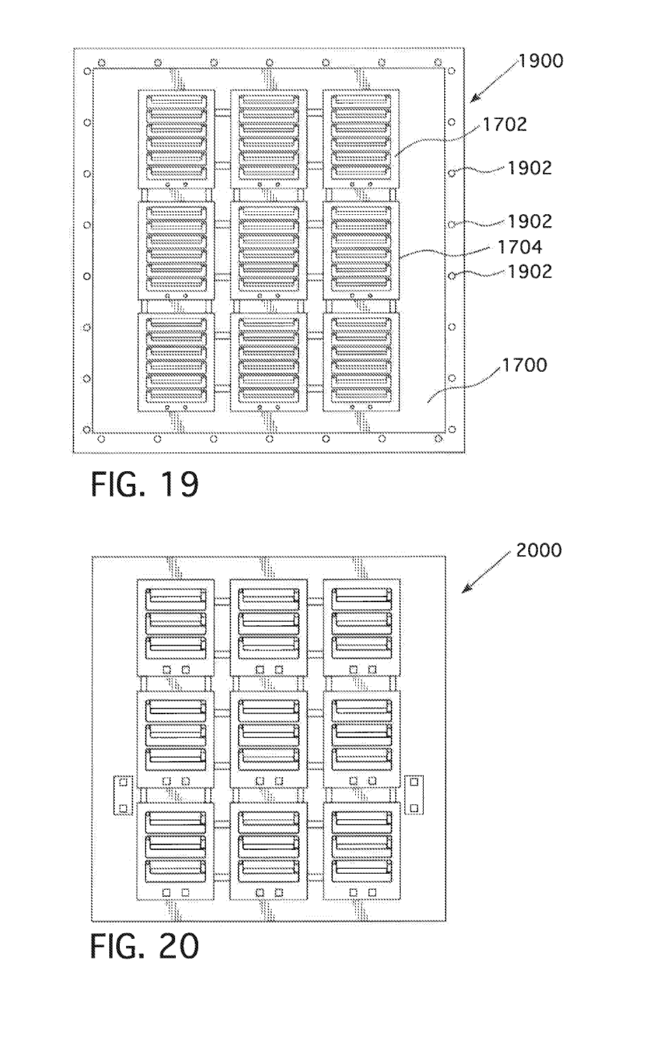

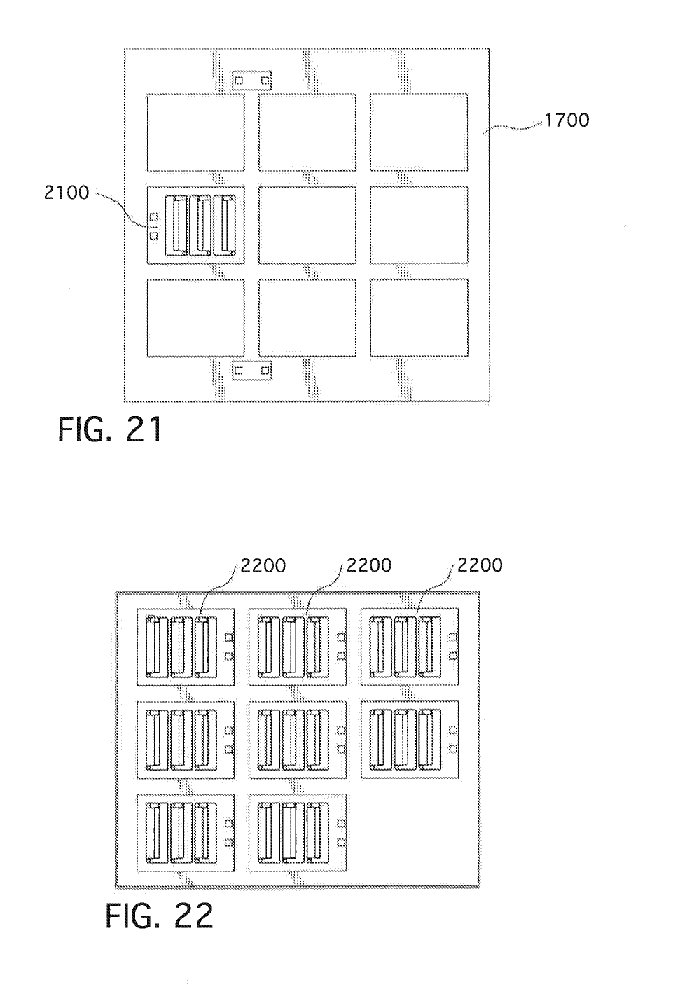

One embodiment of a method for fabricating and singulating individual frameless actuator film actuators will now be described. First, in one embodiment, the plate foil 1700 (or 1800 in another embodiment) is prepared cut in multiple units. As shown, the plate foil 1700 is cut into units 1702, where each unit has a size of about 36 mm×about 42 mm, for example, and defines a pre cut outline 1704. Other numbers of units and sizes may be selected, without limitation. Second, a multi-layer actuator film (e.g., the two-layer [2L] or four-layer [4L] actuator film 806 discussed in connection with FIG. 8) may be used. In the present embodiment, a four-layer (4L) actuator film is selected and an adhesive (e.g., pressure sensitive adhesive) is printed on the four separate layers of the actuator film. Third, the frameless actuator films are laminated. The four layers of the frameless actuator films are aligned. The L4 layer is initially aligned onto the casing foil, followed by an alignment of the L3 layer, the L2 layer, and the L1 layer, in sequence. FIG. 19 shows the four actuator film layers 1900 aligned onto the precut casing foil 1700 shown in FIG. 18 and ready for lamination by vacuum. Once the four layers L4-L1 are aligned, a vacuum is applied through apertures 1902 for reliable lamination. Fourth, singulation may be accomplished using a blade, or other technique discussed above, to cut the laminated actuator film along the precut outlines 1704 of the individual units 1702. FIG. 20 shows the actuator films shown in FIG. 19 after the actuator films are cut and separated from the casing foil 1700 stretch frame. FIG. 21 shows the casing foil 1700 shown in FIG. 19 with one remaining actuator film actuator 2100 left in the stretch frame. FIG. 22 shows eight of the nine actuator film actuators 2200 removed from the casing foil stretch frame shown in FIG. 19.

Various methods for fabricating and singulating individual frameless actuator film actuators according to the present disclosure have been described. In summary, two singulation techniques have been presented. A first method comprises preparing a casing foil of a size similar to the stretch frame, laminating the actuator films, and singulating by cutting both the actuator films and the casing foil. A second method comprises preparing a casing foil, cutting the casing foil into multiple units having roughly the size of the actuator film, holding the components together using friction or plastic films, laminating the actuator films, and singulating the actuator films by cutting with a blade, or other technique discussed above.

The described methods for fabricating and singulating individual frameless actuator film actuators provide several advantages. For example, such methods combine lamination and casing foil in one step. The casing foil can support the frameless film actuators even if removed from the stretch holder. The methods are compatible with frameless film actuators to minimize thickness. Singulation of the film actuators can be done together with casing. Accordingly, the methods provide a simplified lamination, casing, and singulation in one step. The described methods enable the production of frameless film actuators without sacrificing yield and efficiency. The process is compatible with quality control methodologies.

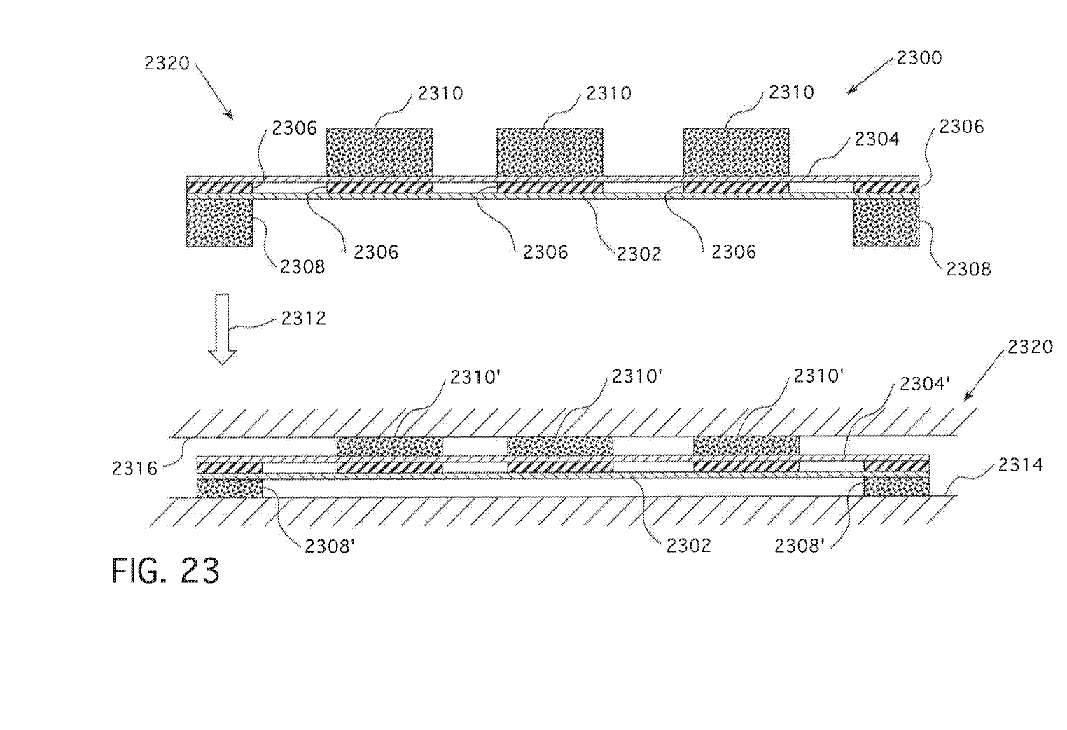

FIG. 23 is a flow diagram 2300 of an installation process of one embodiment of a frameless actuator 2320 to a top plate 2316 and a bottom plate 2314 and compressed thereafter. The embodiment of the frameless actuator 2320 comprises first and second dielectric films 2302, 2304 adhesively attached (e.g., laminated) by film-to-film adhesive 2306. The frameless actuator 2320 also comprises a rigid expandable adhesive 2308 in an expanded state applied to one side of the first dielectric film 2302 and a rigid expandable adhesive 2310 in an expanded state applied to one side of the second dielectric film 2304. In one embodiment, the rigid expandable adhesives 2308 and 2310 have the same expandable but rigid formulation that could collapse and bond under pressure. In one embodiment, the rigid expandable adhesive 2308, 2310 is suitably rigid to hold pre-strain when in an expanded state. In one embodiment, the expandable adhesive 2308, 2310 may be tacky at room temperature and require a release liner. Otherwise, in various embodiments, the expandable adhesive 2308, 2310 may be selected such that it is not tacky at room temperature and, therefore, would not require a release liner. In one embodiment, the expandable adhesive 2308, 2310 collapses and bonds to substrates such as the top and bottom plates 2316, 2314 under pressure. In another embodiment, heat may be added before, during, or after the compressing process.

Accordingly, at process 2312, the frameless actuator 2320 is placed between top and bottom plates 2316, 2314 (e.g., substrates) and then compressed to collapse and bond the expandable adhesive 2308′, 2310′, shown in a collapsed state. In one embodiment, heat may be added during the compression process or after the compression process to bond the expandable adhesive 2308′, 2310′ to the top and bottom plates 2316, 2314.

In one embodiment, the process described in connection with the flow diagram 2300 shown in FIG. 23 may be able to reduce the number of printing steps and the need for release liners but still maintain a thinner profile in the frameless actuator. In various embodiments, a polyurethane or polyolefin material may be employed for this application. In other embodiments, an encapsulated adhesive may be incorporated into the expandable adhesive 2308, 2310 to assist bonding.

FIGS. 24A-24F illustrate various embodiments of a frameless actuator mounted on a curved surface. As previously discussed, a flexible frameless actuator can be configured to mount on a curved surface. Using guide rails on two parallel surfaces allows the actuator to be mounted on small diameter surfaces. FIG. 24A is an actuator module 2400 comprising a top plate 2402 and a bottom plate 2404, each having an arcuate or a curved surface. A frameless actuator 2406, as previously discussed, is located between the top and bottom curved plates 2402, 2404. A siding mechanism comprising at least one guide rail 2408 and ball bearings 2410 provides an actuator that can move linearly as shown in FIGS. 24B, 24C, 24D, and 24F. The guide rails 2408 and the ball bearings 2410 can be placed in a manner such that they conform to the curvature of the top and bottom plates 2402, 2404, the actuator module 2400 can provide rotational movement as shown in FIG. 24E.

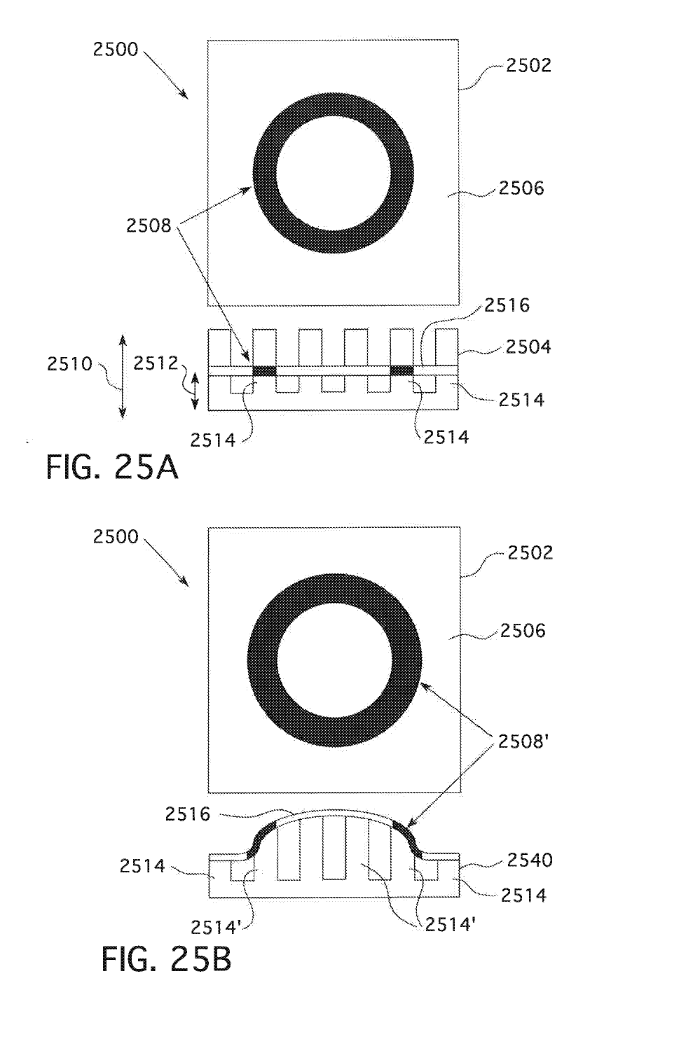

FIGS. 25A and 25B illustrate one embodiment of a configurable actuator element 2500. In one embodiment, the configurable actuator element 2500 is a button. In another embodiment, the configurable actuator element 2500 is a display element. FIG. 25A is a top view 2502 and a side view 2504 of the configurable actuator element 2500 in an unpowered state. FIG. 25B is a top view 2502 and a side view 2540 of the configurable actuator element 2500 in a powered state. The configurable button actuator 2500 comprises an electrode 2508 supported by a dielectric elastomer film 2506 and a plurality of expandable foam structures 2514. In a passive state, when the electrodes 2508 are unpowered, the height 2512 of the expandable foam (or gel) structures 2514 is highly compressed by the stretched dielectric elastomer film 2506, e.g., from a height of about 2 mm down to about 1 mm. The total device height can be about 1 mm small. In an active state, when the electrodes 2508′ are powered, the height 2510 of the expandable foam (or gel) structures 2514′ returns to its original height. In an active state, the regions of powered electrodes 2508′ expand and effectively have a lower modulus. No longer being constrained, the expandable foam (or gel) structures 2514′ are free to expand to their original height 2510. The active regions where the electrodes 2508′ are powered are effectively softer and can stretch to accommodate expansion of the expandable foam structures 2514′. In the region above the expanding expandable foam structures 2514′, the dielectric elastomer film 2516 expands. The area showing a raised portion where the expandable foam structures 2514′ push up against the dielectric elastomer film 2516 can be used as an indicator when an electric field is applied to the electrodes 2508′.

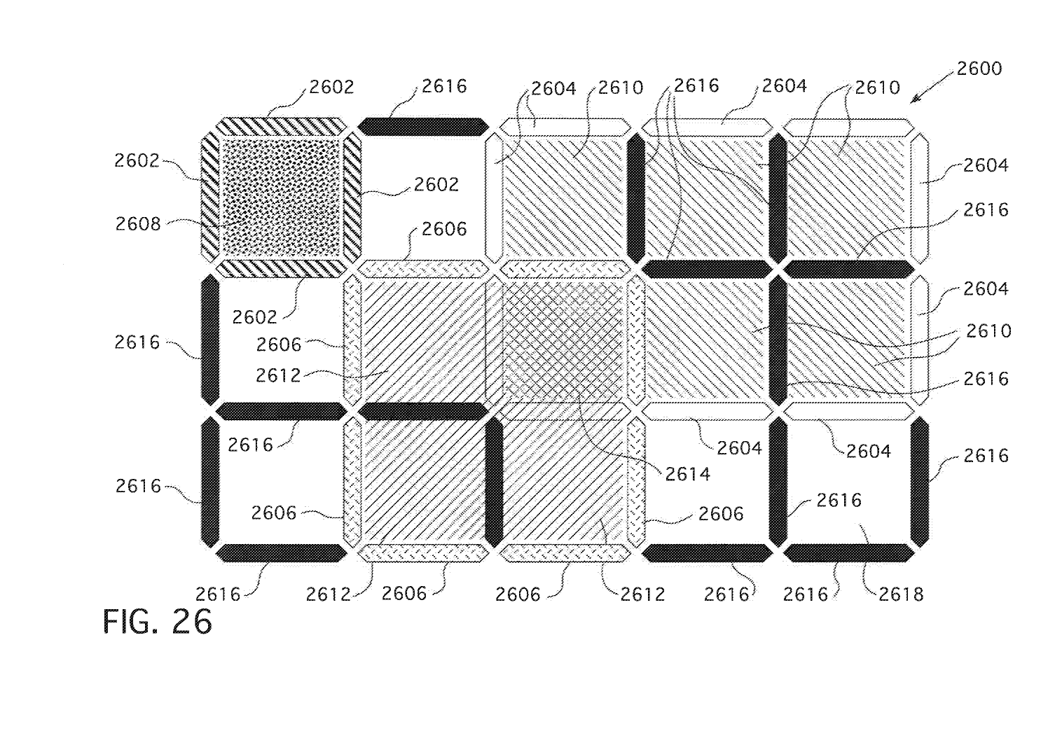

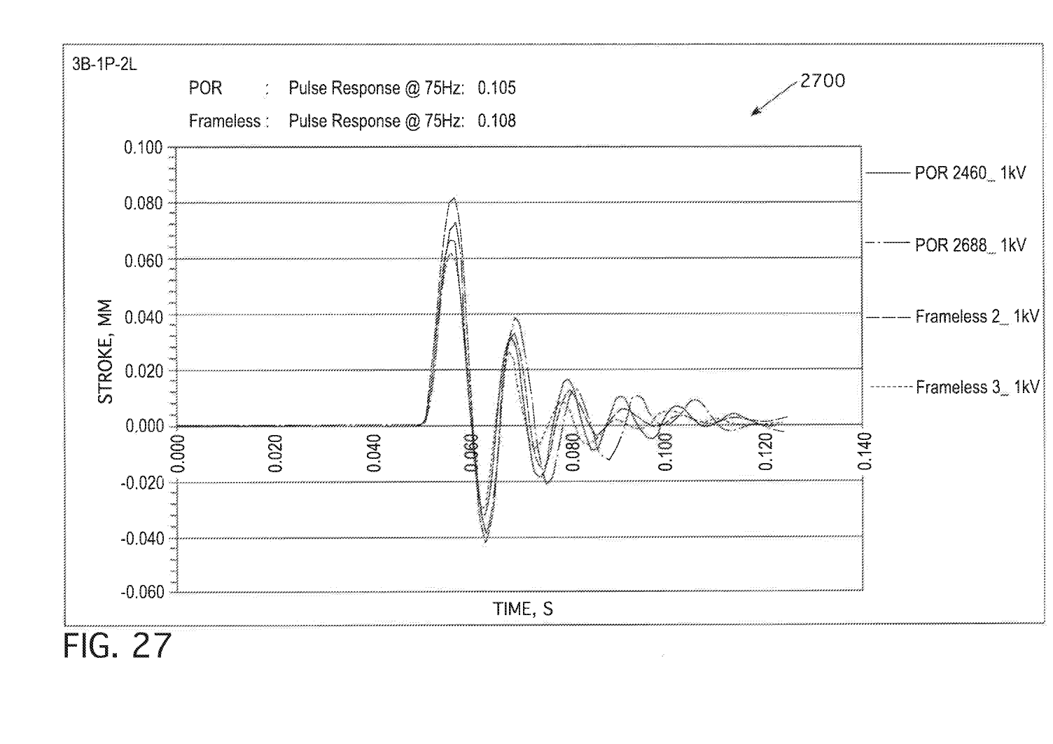

FIG. 26 is one embodiment of a matrix of configurable features 2600 fabricated using the configurable actuator element shown in FIGS. 25A, 25B. As shown in FIG. 26, the matrix of configurable features 2600 comprises a plurality of electrode segments. Controllers can be configured to drive the matrix of configurable features 2600 to address specific segments to expand the energized region. The segments can be energized in any suitable configuration. For example, a first set of segments 2602 are energized to define a first raised feature 2608. A second set of segments 2604 are energized to define a second raised feature 2610. A third set of segments 2606 are energized to define a third raised feature 2612. A fourth raised feature 2614 can be formed when the energized regions overlap. Unenergized segments 2616 do not expand the corresponding regions 2618. It will be appreciated that the various segments of the matrix of configurable features 2600 can be energized in any suitable manner to accomplish a desired configuration of raised features. With different energizing voltages, features can be raised to different heights.

FIG. 27 is a graphical representation 2700 of inertial drive time response for various framed actuators and various embodiments of frameless actuators, according to the present disclosure. Framed and frameless actuators are compared. Stroke (mm) is shown along the vertical axis and Time (s) is shown along the horizontal axis. Framed actuators POR-2460 and POR-2688 and frameless actuators 2 and 3 were energized with a 1 kV pulse at 75 Hz. The pulse response of the framed actuators at 75 kHz was about 0.105 mm. The pulse response of the frameless actuators at 75 kHz was about 0.108 mm. As shown, the two types of actuators produce pulse responses that are substantially the same.

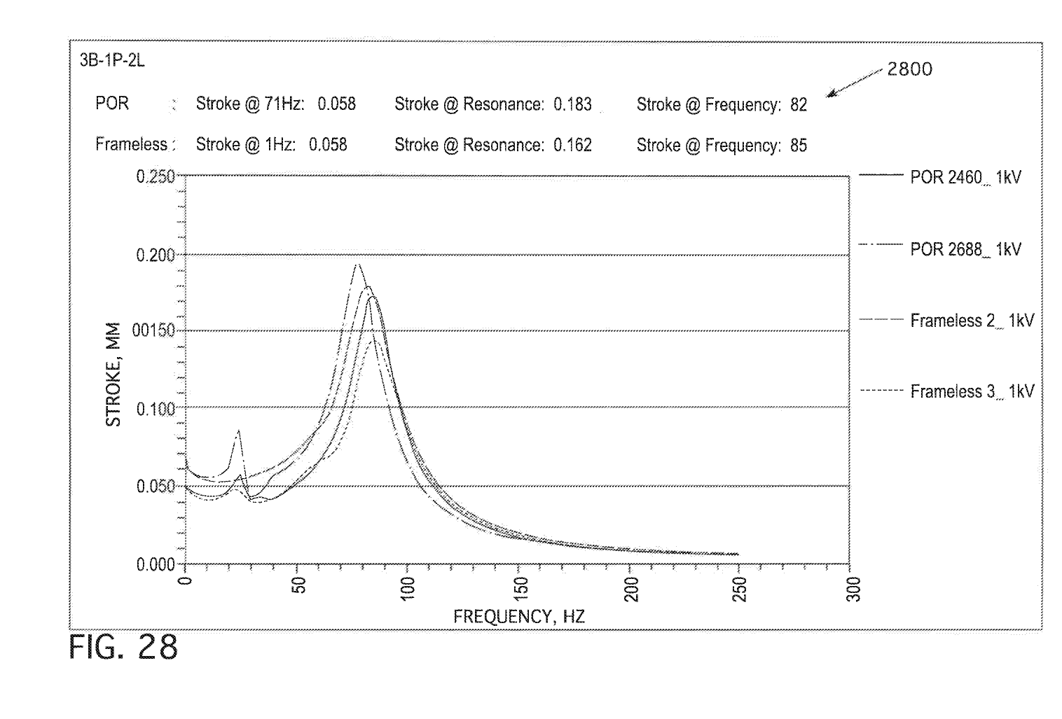

FIG. 28 is a graphical representation 2800 of inertial drive frequency response for various framed actuators and various embodiments of frameless actuators, according to the present disclosure. Framed and frameless actuators are compared. Stroke (mm) is shown along the vertical axis and Frequency (Hz) is shown along the horizontal axis. Framed actuators POR-2460 and POR-2688 and frameless actuators 2 and 3 were energized with a 1 kV electric field in a frequency sweep ranging from 1 to 250 Hz. The stroke at 1 Hz of the framed and frameless actuators was about 0.058 mm. The stroke at resonance was about 0.183 mm for the framed actuators and about 0.162 mm for the frameless actuators. The resonant frequency of the framed actuators is about 82 Hz and the resonant frequency of the frameless actuators was about 85 Hz.

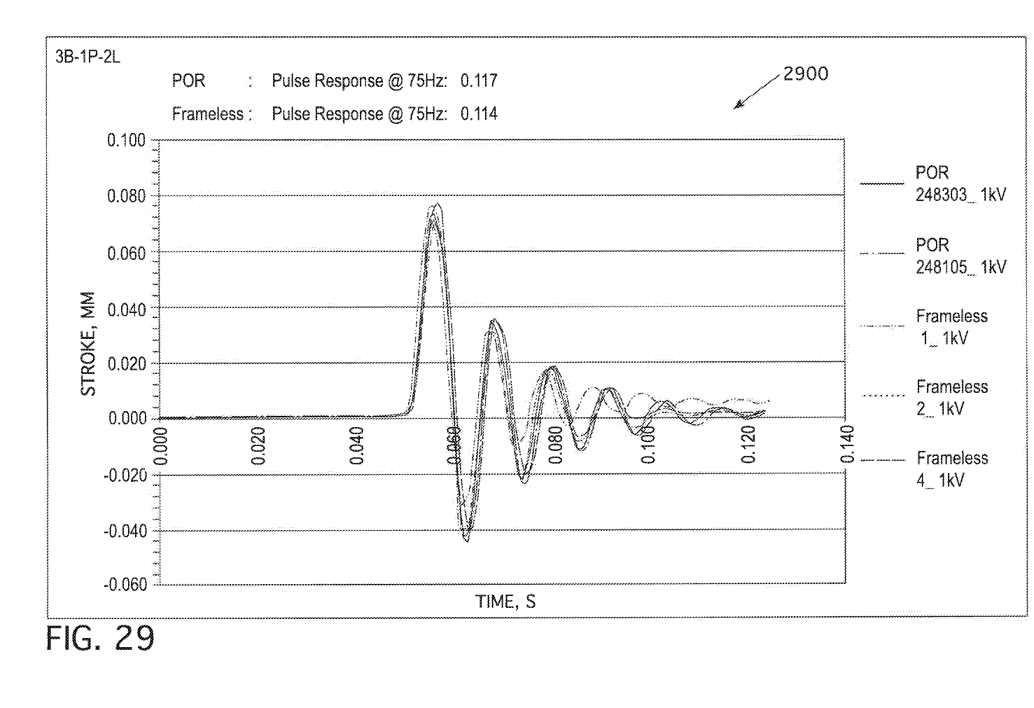

FIG. 29 is a graphical representation 2900 of 3 bar actuator time response for various framed actuators and various embodiments of frameless actuators, according to the present disclosure. Framed and frameless actuators are compared. Stroke (mm) is shown along the vertical axis and Time (s) is shown along the horizontal axis. Framed actuators POR-248303 and POR-248105 and frameless actuators 1, 2, and 4 were energized with a 1 kV pulse at 75 Hz. The pulse response of the framed actuators was about 0.117 mm. The pulse response of the frameless actuators was about 0.114 mm. As shown, the two types of actuators produce pulse responses that are substantially the same.

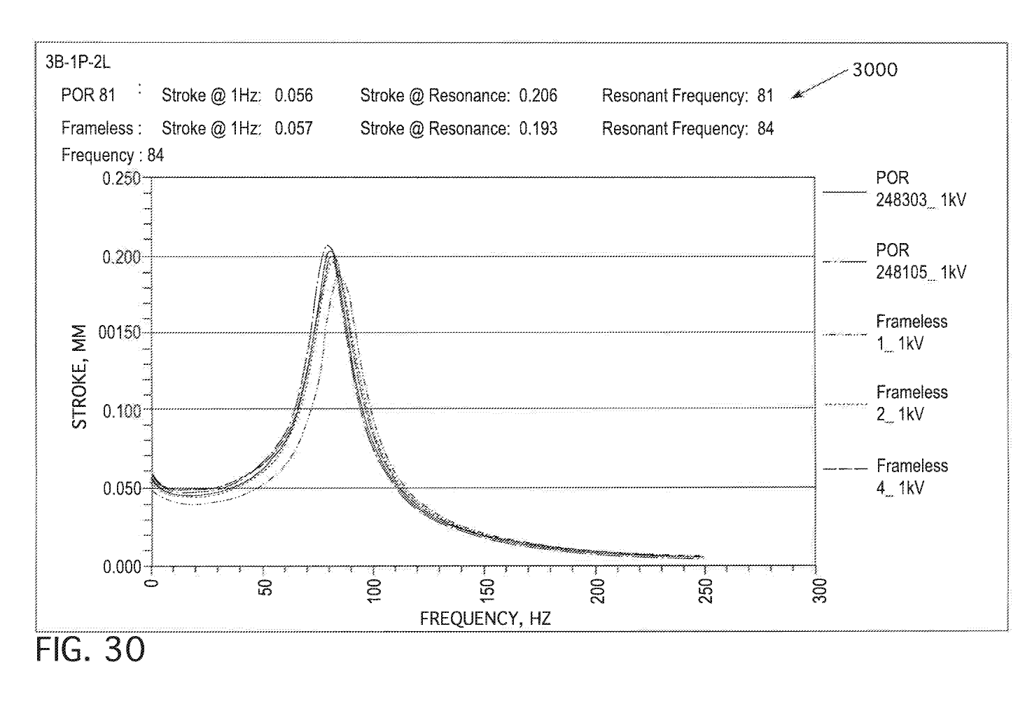

FIG. 30 is a graphical representation 3000 of 3 bar actuator frequency response for various framed actuators and various embodiments of frameless actuators, according to the present disclosure. Framed and frameless actuators are compared. Stroke (mm) is shown along the vertical axis and Frequency (Hz) is shown along the horizontal axis. Framed actuators POR-248303 and POR-248105 and frameless actuators 1, 2, and 4 were energized with a 1 kV electric field in a frequency sweep from 1 to 250 Hz. The stroke at 1 Hz of the framed actuators was about 0.056 mm and for the frameless actuators, the stroke at 1 Hz was about 0.057 mm. The stroke at resonance was about 0.206 mm for the framed actuators and about 0.193 mm for the frameless actuators. The resonant frequency of the framed actuators is about 81 Hz and the resonant frequency of the frameless actuators was about 84 Hz.

Having described various embodiments of frameless actuators, it will be appreciated that a variety of techniques and materials may be employed to fabricate such devices. Accordingly, in various embodiments either very stiff or very strongly adhering adhesives may be employed for an adhesive to support a pre-strained film while being adhered to rigid substrates, such as those of devices, for example. In one embodiment, either the modulus of adhesive or adhesion strength may be greater than the compressive force of a pre-strained film which may be employed in frameless actuator devices. For multilayer frameless actuator devices, the film-to-film adhesive is of lesser concern because the same adhesive, which is either stiff or of strong adhesion, can be used as a film-to-film adhesive. Adhesives are not limited to pressure sensitive and expandable adhesives but can be chosen from a wide range of materials including hot melt adhesives, b-stageable adhesives, and UV curable adhesives. Rigid or high modulus versions of the latter materials may offer the advantage of non-sticky surfaces which do not require the use of release liners.

Broad categories of previously discussed devices include, for example, personal communication devices, handheld devices, and mobile telephones. In various aspects, a device may refer to a handheld portable device, computer, mobile telephone, smartphone, tablet personal computer (PC), laptop computer, and the like, or any combination thereof. Examples of smartphones include any high-end mobile phone built on a mobile computing platform, with more advanced computing ability and connectivity than a contemporary feature phone. Some smartphones mainly combine the functions of a personal digital assistant (PDA) and a mobile phone or camera phone. Other, more advanced, smartphones also serve to combine the functions of portable media players, low-end compact digital cameras, pocket video cameras, and global positioning system (GPS) navigation units. Modern smartphones typically also include high-resolution touch screens (e.g., touch surfaces), web browsers that can access and properly display standard web pages rather than just mobile-optimized sites, and high-speed data access via Wi-Fi and mobile broadband. Some common mobile operating systems (OS) used by modern smartphones include Apple's IOS, Google's ANDROID, Microsoft's WINDOWS MOBILE and WINDOWS PHONE, Nokia's Symbian, RIM's BlackBerry OS, and embedded Linux distributions such as MAEMO and MEEGO. Such operating systems can be installed on many different phone models, and typically each device can receive multiple OS software updates over its lifetime. A device also may include, for example, gaming cases for devices (IOS, ANDROID, WINDOWS PHONES, 3DS), gaming controllers or gaming consoles such as an XBOX console and PC controller, gaming cases for tablet computers (IPAD, GALAXY, XOOM), integrated portable/mobile gaming devices, haptic keyboard and mouse buttons, controlled resistance/force, morphing surfaces, morphing structures/shapes, among others.

It is to be appreciated that the embodiments described herein illustrate example implementations, and that the functional elements, logical blocks, program modules, and circuits elements may be implemented in various other ways which are consistent with the described embodiments. Furthermore, the operations performed by such functional elements, logical blocks, program modules, and circuits elements may be combined and/or separated for a given implementation and may be performed by a greater number or fewer number of components or program modules. As will be apparent to those of skill in the art upon reading the present disclosure, each of the individual embodiments described and illustrated herein has discrete components and features which may be readily separated from or combined with the features of any of the other several embodiments without departing from the scope of the present disclosure. Any recited method can be carried out in the order of events recited or in any other order which is logically possible.

It is worthy to note that any reference to “one embodiment” or “an embodiment” means that a particular feature, structure, or characteristic described in connection with the embodiment is included in at least one embodiment. The appearances of the phrase “in one embodiment” or “in one aspect” in the specification are not necessarily all referring to the same embodiment.

It is worthy to note that some embodiments may be described using the expression “coupled” and “connected” along with their derivatives. These terms are not intended as synonyms for each other. For example, some embodiments may be described using the terms “connected” and/or “coupled” to indicate that two or more elements are in direct physical or electrical contact with each other. The term “coupled,” however, may also mean that two or more elements are not in direct contact with each other, but yet still co-operate or interact with each other.

It will be appreciated that those skilled in the art will be able to devise various arrangements which, although not explicitly described or shown herein, embody the principles of the present disclosure and are included within the scope thereof. Furthermore, all examples and conditional language recited herein are principally intended to aid the reader in understanding the principles described in the present disclosure and the concepts contributed to furthering the art, and are to be construed as being without limitation to such specifically recited examples and conditions. Moreover, all statements herein reciting principles, embodiments, and embodiments as well as specific examples thereof, are intended to encompass both structural and functional equivalents thereof. Additionally, it is intended that such equivalents include both currently known equivalents and equivalents developed in the future, i.e., any elements developed that perform the same function, regardless of structure. The scope of the present disclosure, therefore, is not intended to be limited to the exemplary embodiments and embodiments shown and described herein. Rather, the scope of present disclosure is embodied by the appended claims.

The terms “a” and “an” and “the” and similar referents used in the context of the present disclosure (especially in the context of the following claims) are to be construed to cover both the singular and the plural, unless otherwise indicated herein or clearly contradicted by context. Recitation of ranges of values herein is merely intended to serve as a shorthand method of referring individually to each separate value falling within the range. Unless otherwise indicated herein, each individual value is incorporated into the specification as if it were individually recited herein. All methods described herein can be performed in any suitable order unless otherwise indicated herein or otherwise clearly contradicted by context. The use of any and all examples, or exemplary language (e.g., “such as,” “in the case,” “by way of example”) provided herein is intended merely to better illuminate the invention and does not pose a limitation on the scope of the invention otherwise claimed. No language in the specification should be construed as indicating any non-claimed element essential to the practice of the invention. It is further noted that the claims may be drafted to exclude any optional element. As such, this statement is intended to serve as antecedent basis for use of such exclusive terminology as solely, only and the like in connection with the recitation of claim elements, or use of a negative limitation.

Groupings of alternative elements or embodiments disclosed herein are not to be construed as limitations. Each group member may be referred to and claimed individually or in any combination with other members of the group or other elements found herein. It is anticipated that one or more members of a group may be included in, or deleted from, a group for reasons of convenience and/or patentability.

While certain features of the embodiments have been illustrated as described above, many modifications, substitutions, changes and equivalents will now occur to those skilled in the art. It is therefore to be understood that the appended claims are intended to cover all such modifications and changes as fall within the scope of the disclosed embodiments and appended claims.

What is claimed is:

1. A frameless film actuator, comprising:
a frameless actuator film comprising at least one elastomeric dielectric film disposed at least partially between first and second electrodes;
an adhesive applied on at least one portion of one side of the frameless actuator film.

2. The frameless film actuator according to claim 1, further including:
a second adhesive applied on at least one portion of an opposite side of the frameless actuator film.

3. The frameless film actuator according to one of claims 1 and 2, wherein the adhesive is chosen from a group consisting of pressure sensitive adhesives, expandable adhesives, hot melt adhesives, b-staged adhesives, and UV curable adhesives.

4. The frameless film actuator according to any one of claims 1 to 3, further including:
a release liner applied to the adhesive.

5. The frameless film actuator according to claim 2, further including:
a first release liner applied to the first adhesive; and
a second release liner applied to the second adhesive.

6. The frameless film actuator according to any one of claims 1 to 5, further comprising a disposable frame coupled to the actuator film to support a pre-stretched actuator film before it is attached to a rigid substrate.

7. The frameless film actuator according to claim 6, wherein the disposable frame is formed of pressure sensitive adhesive.

8. The frameless film actuator according to any one of claims 1 to 7, wherein the frameless actuator film comprises two or more layers of elastomeric dielectric film.

9. The frameless film actuator according to claim 8, wherein the actuator film comprises four layers of elastomeric dielectric film.

10. The frameless film actuator according to claim 8, wherein the two or more layers of the elastomeric dielectric films are laminated with a film-to-film adhesive.

11. The frameless film actuator according to claim 4, further including a removable adhesive applied to at least a portion of the release liner.

12. The frameless film actuator according to claim 4, further including a release layer applied to at least a portion of the one or more layers of the elastomeric dielectric film.

13. The frameless film actuator according to any one of claims 1 to 12, comprising a substantially flat rigid top plate surface and a substantially flat rigid bottom plate surface, wherein the frameless actuator film is slidably disposed between the top and bottom plates.

14. The frameless film actuator according to any one of claims 1 to 12, comprising a curved rigid top plate surface and a curved rigid bottom plate surface, wherein the frameless actuator film is slidably disposed between the top and bottom plates.

15. A method of fabricating a frameless film actuator, the method comprising:
pre-stretching an elastomeric dielectric film, the pre-stretched elastomeric dielectric film having a top side and a bottom side;
joining the pre-stretched elastomeric dielectric film to a temporary frame material, wherein the frame material is sufficiently strong to support the pre-strain of the pre-stretched elastomeric dielectric film;
applying electrodes and bus bars to at least one side of the pre-stretched elastomeric dielectric film; and
applying adhesive to at least one side of the pre-stretched elastomeric dielectric film.

16. The method according to claim 15, wherein one or more windows are formed in the frame material.

17. The method according to one of claims 15 and 16, wherein the frame material is a ripstop material.

18. The method according to any one of claims 15 to 17, further comprising applying at least one release liner to the adhesive.

19. The method according to any one of claims 15 to 18, wherein the frame is configured to support multiple frameless film actuators and singulating the actuators.

20. The method according to any one of claims 15 to 19, wherein at least one of the frame and adhesive materials is a rigid expandable material and the rigid expandable material is compressed between top and bottom substrates.

21. The method according to claim 20, further comprising applying heat to the expandable adhesive before, during, or after the compressing process.

22. A configurable actuator element, comprising:
a dielectric elastomer film;
an electrode supported by the dielectric elastomer film;
a plurality of expandable foam structures positioned relative to the dielectric elastomer film and the electrode, wherein the plurality of expandable foam structures positioned relative to the dielectric elastomer film and the electrode assume a first height when the electrode is not energized and a second height when the electrode is energized.

23. The configurable actuator element according to claim 22, wherein when the electrode is not energized the dielectric elastomer film is stretched planarly and the plurality of expandable foam structures are compressed by the stretched dielectric elastomer film to the first height.

24. The configurable actuator element according to claim 23, wherein when the electrode is energized the plurality of expandable foam structures expand and push against the dielectric elastomer film to raise the dielectric elastomer film from the first height to the second height.

25. An array of configurable actuator elements according to claim 22, wherein the elements can be energized separately to enable different portions of the elastomer film to rise to different heights.
